(19) United States
(12) Patent Application Publication
(10) Pub. No.: US 2014/0182665 A1
(43) Pub. Date: Jul. 3, 2014

(54) Optical Absorbers

(71) Applicant: INTERMOLECULAR, INC., San Jose, CA (US)

(72) Inventor: Haifan Liang, Fremont, CA (US)

(73) Assignee: INTERMOLECULAR, INC., San Jose, CA (US)

(21) Appl. No.: 13/727,986

(22) Filed: Dec. 27, 2012

(51) Int. Cl. H01L 31/032; H01L 31/18

(52) U.S. Cl. CPC H01L 31/0324; H01L 31/18
USPC 136/252; 438/93

(57) ABSTRACT

Optical absorbers, solar cells comprising the optical absorbers, and methods for making the absorbers are disclosed. The optical absorber comprises a layer comprising a semiconductor having a bandgap of between about 1.0 eV and about 1.6 eV on a substrate. The thickness of the layer is from about 1 to about 10 microns. The semiconductor comprises Fe, at least one Group IVA element, and at least one Group VIA element. The Group VIA element can be S, Se or Te. The Group IVA element can be Si or Ge. Typical compositions are Fe₂(Si,Ge)(S,Se)₄. The bandgap can be graded through the thickness of the absorber. High Productivity Combinatorial methods can be used to optimize the composition and grading.

### CROSS-REFERENCE TO RELATED APPLICATION

This application is related to U.S. patent application Ser. No. ______ filed on ______, 201X, having internal attorney docket no. IM0918_US, which is herein incorporated by reference for all purposes.

### FIELD OF THE INVENTION

One or more embodiments of the present invention relate to methods of manufacture of optical absorbers suitable for use in solar cells.

### BACKGROUND

The increasing demand for environmentally friendly, sustainable and renewable energy sources is driving the development of large area, thin film photovoltaic (TFPV) devices. With a long-term goal of providing a significant percentage of global energy demand, there is a concomitant need for Earth-abundant, high conversion efficiency materials for use in photovoltaic devices. A number of Earth abundant, direct-bandgap semiconductor materials now seem to show evidence of the potential for both high efficiency and low cost in Very Large Scale (VLS) production (e.g., greater than 100 GW), yet their development and characterization remains difficult because of the complexity of the materials systems involved.

Among the TFPV technologies, CuInₓGa₁₋ₓSe₂ (CIGS) and CdTe are the two that have reached volume production with greater than 11% stabilized module efficiencies. However, the supply of In, Ga and Te may impact annual production of CIGS and CdTe solar panels. Moreover, price increases and supply constraints in Ga and In could result from the aggregate demand for these materials used in flat panel displays (FPDs) and light-emitting diodes (LEDs) along with CIGS TFPV. Also, there are concerns about the toxicity of Cd throughout the lifecycle of the CdTe TFPV solar modules. Efforts to develop devices that leverage manufacturing and R&D infrastructure related to these TFPV technologies but using more widely available and more environmentally friendly materials should be considered a top priority for research. The knowledge and infrastructure developed around CdTe and CIGS TFPV technologies can be leveraged to allow faster adoption of new TFPV materials systems.

Optical absorbers for use with solar cells are more economically attractive if they have high efficiency and can be made from earth-abundant materials that are available at low cost. CIGS absorbers have been widely studied to meet these performance goals. CIGS has a strong absorption coefficient for visible light making it possible to use thinner absorber layers further reducing costs of assembled solar cells. Another material that has been explored in some detail is “CZTS,” which comprises Cu, Zn, Sn, and Se. (In both families of materials, S can be substituted for some or all of the Se.)

It is also possible to make similar absorbers using various other combinations of earth-abundant materials, but these have not yet been developed as extensively, and their performance potential is not yet known. Some of these materials are described in co-pending U.S. patent application Ser. No. ______, incorporated herein by reference. Another material that has been described is Cu₂SnS₃ for which some preliminary studies have been reported by Devendra et al. (“Direct Liquid-Coated Cu₂SnS₃ as a New Absorber Material for Thin-Film Solar Cell,” 38^{th} IEEE PVSC, 2012), Berg, et al. (“Thin film solar cells based on the ternary compound Cu₂SnS₃,” Thin Solid Films, 520, 6291-94, 2012), Bouaziz et al. (“Growth of Cu₂SnS₃ thin films by solid reaction under sulphur atmosphere,” Vacuum, 85, 783-86, 2011), and Fernandes et al. (“A study of ternary Cu₂SnS₃ and Cu₃SnS₄ thin films prepared by sulfurizing stacked metal precursors,” J. Phys. D: Appl. Phys., 43, 215403, 2010).

It is also possible to make similar absorbers using Fe instead of Cu. Such absorbers have not yet been studied extensively. Yu et al. (“Iron Chalcogenide Photovoltaic Absorbers,” Adv. Energy Mater., 1, 748-53, 2011) provide some characterization of spin-coated films of Fe₂SiS₄ and Fe₂GeS₄, but complete solar cells based on such materials have not been fabricated or tested, the optimization of the possible composition variations has not been performed, and practical production methods of fabrication have not been developed.

The development of TFPV devices exploiting Earth abundant materials represents a daunting challenge in terms of the time-to-commercialization. That same development also suggests an enticing opportunity for breakthrough discoveries. A quaternary system such as CIGS requires management of multiple kinetic pathways, thermodynamic phase equilibrium considerations, defect chemistries, and interfacial control. The vast phase-space to be managed includes process parameters, source material choices, compositions, and overall integration schemes. The complexity of the intrinsically-doped, self-compensating, multinary, polycrystalline, queue-time-sensitive, thin-film absorber (CIGS), and its interfaces to up-, and down-stream processing, combined with the lack of knowledge on a device level to address efficiency losses effectively, makes it a highly empirical material system. The performance of any thin-film, (opto-)electronically-active device is extremely sensitive to its interfaces. Interface engineering for electronically-active devices is highly empirical. Traditional R&D methods are ill-equipped to address such complexity, and the traditionally slow pace of R&D could limit any new material from reaching industrial relevance when having to compete with the incrementally improving performance of already established TFPV fabrication lines, and continuously decreasing panel prices for more traditional cSi PV technologies.

Due to the complexity of the material, cell structure, and manufacturing process, both the fundamental scientific understanding and large scale manufacturability are yet to be realized for TFPV devices. As the photovoltaic industry pushes to achieve grid parity, much faster and broader investigation is needed to explore the material, device, and process windows for higher efficiency and a lower cost of manufacturing process. Efficient methods for forming different types of TFPV devices that can be evaluated are necessary.

### SUMMARY OF THE INVENTION

Optical absorbers, solar cells comprising the optical absorbers, and methods for making the absorbers are disclosed. The optical absorber comprises a layer comprising a semiconductor having a bandgap of between about 1.0 eV and about 1.6 eV on a substrate. The thickness of the layer can be from about 1 to about 10 microns. In some embodiments, the thickness of the layer can be from about 1 micron to about 3 microns. The semiconductor comprises Fe, at least one Group IVA element, and at least one Group VIA element. The Group VIA element can be S, Se or Te. The Group IVA element can be Si or Ge. Most generally, the semiconductor comprises a compound having the formula Feₓ(CₐSi_{b}Ge_{c}Sn_{d}Pbₑ)(S_{f}Se_{g}Teₕ)_{y}, wherein 1.8<x<2.2, and 3.5<y<4.5, wherein a+b+c+d+e=1, and wherein f+g+h=1. In some embodiments, the compound has the formula Feₓ(Si_{b}Ge_{1-b})(S_{f}Se_{1-f})_{y}, where x=2, y=4, 0≦b≦1, and 0≦f≦1.

The bandgap can be graded through the thickness of the layer. In some embodiments, the bandgap is graded by varying the value of one or more of a, b, c, d, e, f g, or h. In some embodiments, the bandgap is graded through the thickness of the layer by varying the value of one or more of b or f. In some embodiments, the bandgap is single-graded through the thickness of the layer. In some embodiments, the bandgap is double-graded through the thickness of the layer. The bandgap can be continuously or step-wise graded through the thickness of the layer. A solar cell comprising the optical absorber can further comprise a front contact electrode, a back contact electrode, and a buffer layer.

Methods of forming an optical absorber comprise forming a first layer on a substrate, the first layer comprising Fe and at least one Group IVA element, and exposing the first layer to a gas at between about 100 Torr and about 800 Torr comprising at least one Group VIA element. The optical absorber comprises a semiconductor having a bandgap between about 1.0 eV and 1.6 eV. The first layer as initially formed contains no O. The thickness of the layer can be from about 1 to about 10 microns. In some embodiments, the thickness of the layer can be from about 1 micron to about 3 microns.

The exposing the first layer can include heating the first layer to a temperature between 20° C. and about 1000° C., typically to a temperature between about 100° C. and about 600° C., more typically to a temperature between about 200° C. and about 400° C. In some embodiments, the exposing further comprises heating the layers to between about 100° C. and about 600° C. In some embodiments, the exposing further comprises heating the layers to between about 200° C. and about 500° C. In some embodiments, the methods further comprise annealing the layers at a temperature of between about 350° C. and about 650° C. The exposing or annealing steps can be performed in a batch system, or in an in-line system.

The Group VIA element can be S, Se or Te. The Group IVA element most typically can be Si or Ge. The semiconductor generally comprises a compound having the formula Feₓ(CₐSi_{b}Ge_{c}Sn_{d}Pbₑ)(S_{f} Se_{g}Teₕ)_{y}, wherein 1.8<x<2.2, and 3.5<y<4.5, wherein a+b+c+d+e=1, and wherein f+g+h=1. In some embodiments, the semiconductor comprises a compound having the formula Feₓ(Si_{b}Ge_{1-b})(S_{f}Se_{1-f})_{y}, where x=2, y=4, 0≦b≦1, and 0≦f≦1.

The methods can further comprise forming a second layer comprising Fe and at least one Group IVA element on the first layer, and exposing the second layer to a gas, the gas comprising at least one Group VIA element. Additional layers can be formed if desired.

The methods can further comprise grading the bandgap. The bandgap can be graded through the thickness of the first layer, or if multiple layers are present, through the thickness of the layer stack. In some embodiments, grading the bandgap comprises varying the value of one or more of a, b, c, d, e, f g, or h. In some embodiments, grading the bandgap comprises varying the value of one or more of b or f. In some embodiments, grading the bandgap comprises forming a second layer on the first layer, wherein the bandgap of the second layer is different from the bandgap of the first layer. The second layer can comprise a semiconductor having the formula Fₑₓ(_{Ca}S_{ib}G_{ec}S_{nd}P_{be})(_{Sf}S_{eg}T_{eh)y}, wherein 1.8<x<2.2, and 3.5<y<4.5, wherein a+b+c+d+e=1, wherein f+g+h=1, and wherein one or more of a, b, c, d, e, f g, or h is different in the second layer from the first layer. In some embodiments, grading the bandgap comprises varying the values of at least one of a, b, c, d, or e through the thickness of the first layer. In some embodiments, grading the bandgap comprises varying the values of at least one of f g, or h through the thickness of the first layer.

In some embodiments, the relative amounts of the at least one Group IVA element and the at least one Group VIA element are varied in a combinatorial manner among a plurality of discrete site-isolated regions (SIRs) designated on the substrate.

In some embodiments, the methods can further comprise depositing a front contact electrode, a buffer layer, and a back contact electrode to prepare a solar cell comprising the absorber layer. The buffer layer can comprise CdS.

In some embodiments, methods of forming an optical absorber comprise forming a first layer by physical vapor deposition (PVD) from one or more sputtering targets, and exposing the first layer to a gas comprising at least one Group VIA element, wherein at least one sputtering target comprises Fe, at least one sputtering target comprises a IVA element, and wherein the optical absorber comprises a semiconductor having a bandgap between about 1.0 eV and 1.6 eV. The thickness of the layer can be from about 1 to about 10 microns. In some embodiments, the thickness of the layer can be from about 1 micron to about 3 microns.

In some embodiments, the one or more sputtering targets comprise elemental targets, binary targets, ternary targets, quaternary targets or quinternary targets. In some embodiments, each elemental target comprises Fe, Si, or Ge. In some embodiments, the PVD comprises reactive sputtering in an atmosphere comprising one or more of S or Se.

In some embodiments, each binary target comprises Fe and S, Fe and Se, Fe and Si, Fe and Ge, Si and S, Si and Se, Si and Ge, Ge and S, or Ge and Se. In some embodiments each binary target comprises compounds, mixtures or alloys comprising Fe and S, Fe and Se, Si and S, Si and Se, Ge and S, or Ge and Se. Targets comprising mixtures can be made with arbitrary composition ratios, by, for example, sintering arbitrary ratios of mixed elemental powders. In some embodiments, the PVD comprises reactive sputtering in an atmosphere comprising one or more of S or Se.

In some embodiments, each ternary target comprises Fe, Si, and S; Fe, Si, and Se; Fe, Ge, and S; Fe, Ge, and Se; Fe, Si and Ge, Si, Ge and S, Si, Ge and Se. In some embodiments each ternary target comprises compounds, mixtures or alloys comprising Fe, Si, and S; Fe, Si, and Se; Fe, Ge, and S; Fe, Ge, and Se; Fe, Si and Ge, Si, Ge and S, Si, Ge and Se. Targets comprising mixtures can be made with arbitrary composition ratios, by for example, sintering arbitrary ratios of mixed elemental powders. In some embodiments, the PVD comprises reactive sputtering in an atmosphere comprising one or more of S or Se.

In some embodiments, each quaternary target comprises Fe, Si, Ge, and S; Fe, Si, Ge, and Se; Fe, Si, S and Se; or Fe, Ge, S and Se. In some embodiments each quaternary target comprises compounds, mixtures or alloys comprising Fe, Si, Ge, and S; Fe, Si, Ge, and Se; Fe, Si, S and Se; or Fe, Ge, S and Se. Targets comprising mixtures can be made with arbitrary composition ratios, by for example, sintering arbitrary ratios of mixed elemental powders. In some embodiments, the PVD comprises reactive sputtering in an atmosphere comprising one or more of S or Se.

In some embodiments, each quinternary target comprises Fe₂(Si,Ge)(S,Se)₄, with varying amounts of at least one of Si or Ge and S or Se in different quinternary targets. In some embodiments each quinternary target comprises compounds, mixtures or alloys comprising Fe, Si, Ge, and S and Se. Targets comprising mixtures can be made with arbitrary composition ratios, by for example, sintering arbitrary ratios of mixed elemental powders. In some embodiments, the PVD comprises reactive sputtering in an atmosphere comprising one or more of S or Se.

The methods can further comprise grading the bandgap through the thickness of the first layer. In some embodiments, the grading the bandgap comprises varying the relative amount of material sputtered from each of the one or more sputtering targets. In some embodiments, the grading the bandgap comprises forming a second layer on the first layer, wherein the second layer comprises Fe and at least one Group IVA element, wherein the amount of the at least one Group IVA element is different between the first and second layer. In some embodiments, the grading the bandgap comprises forming a second layer on the first layer, wherein the second layer comprises Fe and at least one Group IVA element, wherein the amount of the at least one Group VIA element is different between the first and second layer after the exposing step. In some embodiments, the amount of both the at least one Group IVA element and the amount of the at least one Group VIA element is different between the first and second layer.

In some embodiments, the methods can further comprise designating a plurality of site-isolated regions on the substrate, and varying PVD process parameters among the plurality of site-isolated regions in a combinatorial manner. Methods of forming an optical absorber can comprise designating a plurality of discrete site-isolated regions (SIRs) on a substrate, forming a semiconductor layer on at least one of the plurality of SIRs on the substrate, and characterizing each semiconductor layer formed on the discrete SIRs. The semiconductor generally comprises a compound of the formula Feₓ(CₐSi_{b}Ge_{c}Sn_{d}Pbₑ)(S_{f} Se_{g}Teₕ)_{y}, wherein 1.8<x<2.2, and 3.5<y<4.5, wherein a+b+c+d+e=1, and wherein f+g+h=1. The methods can further comprise varying one or more process parameters for forming each layer on the plurality of SIRs is varied in a combinatorial manner.

In some embodiments, the process parameters can include process material amounts, reactant species, processing temperatures, processing times, processing pressures, processing flow rates, processing powers, processing reagent compositions, the rates at which the reactions are quenched, atmospheres in which the processes are conducted, an order in which materials are deposited. In some embodiments, the characterizing each semiconductor layer comprises measuring a structure or performance parameter for each of the plurality of site-isolated regions. In some embodiments, the structure or performance parameter is one or more of crystallinity, grain size, lattice parameter, crystal orientation, bandgap, optical absorption, efficiency, resistivity, carrier concentration, carrier mobility, minority carrier lifetime, optical absorption coefficient, surface roughness, adhesion, or thermal expansion coefficient.

Thin film stacks can also be provided comprising one or more layers comprising Fe and at least one Group IVA element, wherein the first layer contains no O. The thin film stacks can be exposed to a gas comprising at least one Group VIA element to prepare a semiconductor having a bandgap between about 1.0 eV and 1.6 eV to be used as an optical absorber in a solar cell or other optoelectronic device.

### BRIEF DESCRIPTION OF THE DRAWINGS

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a simple substrate TFPV stack according to an embodiment described herein.

FIG. 4 illustrates a schematic diagram of a simple n-superstrate TFPV stack according to an embodiment described herein.

FIG. 5 illustrates a schematic diagram of a simple p-superstrate TFPV stack according to an embodiment described herein.

FIG. 6 provides a flow chart for a generic 2-step process.

FIG. 7 provides a flow chart for a generic 3-step process.

FIG. 8 illustrates an absorber layer having a flat Ge profile and a flat bandgap profile.

FIG. 9 illustrates an absorber layer having a single graded Ge profile and a single graded bandgap profile.

FIG. 10 illustrates an absorber layer having a single graded Ge profile, a double graded S profile, and a double graded bandgap profile.

FIG. 11 illustrates an absorber layer having a double graded Ge profile and a double graded bandgap profile.

FIG. 12 sets forth a flowchart of method steps in a process sequence for forming an optical absorber layer, according to embodiments of the invention.

FIG. 13 sets forth a flowchart of method steps in a process sequence for forming an optical absorber layer, according to embodiments of the invention.

### DETAILED DESCRIPTION

Before the present invention is described in detail, it is to be understood that unless otherwise indicated this invention is not limited to specific semiconductor devices or to specific semiconductor materials. Exemplary embodiments will be described for solar cells, but other devices can also be fabricated using the methods disclosed. It is also to be understood that the terminology used herein is for the purpose of describing particular embodiments only and is not intended to limit the scope of the present invention.

It must be noted that as used herein and in the claims, the singular forms “a,” “and” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%. Where the modifier “substantially equal to” is used, the two quantities may vary from each other by no more than 5%.

### DEFINITIONS

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

As used herein, “CIGS” will be understood to represent the entire range of related alloys denoted by Cu_{z}In₁₋ₓGaₓS_{(2+w)(1-y)}Se_{(2+w)y}, where 0.5≦z≦1.5, 0≦x≦1, 0≦y≦1, −0.2≦w≦0.5. Similarly, as noted above, other materials (i.e. Ag, Au, Te, etc.) may be incorporated into potential absorber layers, (with e.g., Ag replacing part or all of the Cu, and Te replacing part or all of the Se and/or S). Also as mentioned previously, any of these materials may be further doped with a suitable dopant. As used herein, “CIGSSe”, “CIGSe”, and “CIGS” will be defined as equivalent and will be used interchangeably and will include all compositions including Cu—In—Ga—Se—S, Cu—In—Ga—Se, and Cu—In—Ga—S. Furthermore, “CIGS” also includes other IB-IIIA-VIA alloys, like (Ag,Cu)(In,Ga)(Se), or (Cu)(In,Ga)(S,Se,Te), and the like.

As used herein, “CZTS” will be understood to represent the entire range of related alloys denoted by Cu_{z}Zn₍₁₋ₓ₎SnₓS_{(2+w)(1-y)}Se_{(2+w)y}, where 0.5≦z≦2.0, 0≦x≦1, 0≦y≦1, −0.2≦w≦0.5. Similarly, as noted above, other materials (i.e. Ag, Au, Te, etc.) may be incorporated into potential absorber layers, (with e.g. Ag replacing part or all of the Cu, and Te replacing part or all of the Se and/or S). Also as mentioned previously, any of these materials may be further doped with a suitable dopant. As used herein, “CZTSSe”, “CZTSe”, and “CZTS” will be defined as equivalent and will be used interchangeably and will include all compositions including Cu—Zn—Sn—Se—S, Cu—Zn—Sn—Se, and Cu—Zn—Sn—S. Furthermore, “CZTS” also includes other IB-IIB-IVA-VIA alloys, like (Ag,Cu)Zn(Si,Ge,Sn,Pb)(Se), or (Cu)Zn(Sn,Ge)(S,Se,Te), and the like.

As used herein, the notation “(IIIA)” will be understood to represent the sum of the concentrations of all Group-IIIA elements. This notation will be used herein in calculations of the composition ratios of various elements. This notation will be understood to extend to each of the other Groups of the periodic table respectively (e.g. “(IA)”, “(IIA)”, “(IVA)”, “(VIA)”, “(IB)”, “(IIB)”, etc.). Group designations follow the CAS (American) conventions.

As used herein, the notation “Cu—Zn—Sn” and “Cu(Zn, Sn)” will be understood to include a material containing these elements in any ratio. The notation is extendable to other materials and other elemental combinations.

As used herein, the notation “CuₓZn_{y}Sn_{z}” will be understood to include a material containing these elements in a specific ratio given by x, y, and z (e.g. Cu₇₅Zn₁₅Sn₁₀ contains 75 atomic % Cu, 15 atomic % Zn, and 10 atomic % Sn). The notation is extendable to other materials and other elemental combinations.

As used herein, the notation “Feₓ(CₐSi_{b}Ge_{c}Sn_{d}Pbₑ)(S_{f}Se_{g}Teₕ)_{y}” will be understood to include a material containing Fe, a Group IVA element and a Group VIA element in ratios given by x and y. Within the Group IVA elements the relative composition is given by a, b, c, d, and e; and within the Group VIA elements, the relative composition is given by f, g, and h. The notation is extendable to other materials and other elemental combinations.

As used herein, “metal chalcogenide” or “chalcogenide” will be understood to represent the entire range of related compounds denoted by “MX” where M represents one or more metal elements and X represents one or more of the chalcogen elements (e.g., O, S, Se, or Te).

As used herein, “chalcogenize” and “chalcogenization” will be understood to represent the process by which one or more metals are converted to chalcogenide compounds by exposing the one or more metals to a chalcogen (e.g., O, S, Se, or Te) at elevated temperature (e.g. between 100° C. and 700° C.). Specifically, “selenization” will be understood to represent the process by which one or more metals are converted to selenide compounds by exposing the one or more metals to a Se source at elevated temperature (e.g., between 100° C. and 700° C.). Specifically, “sulfurization” will be understood to represent the process by which one or more metals are converted to sulfide compounds by exposing the one or more metals to a S source at elevated temperature (e.g., between 100° C. and 700° C.). In addition, “chalcogenize” or “chalcogenization” will be understood to represent the process by which a metal precursor is either partially or completely converted to the final multinary chalcogenide compound(s). Similarly, “chalcogenize” or “chalcogenization” will be understood to represent the process by which a precursor containing one or more chalcogenide materials with/without one or more elemental or alloy metals is converted to one or more dense, polycrystalline, desired multinary chalcogenide compound(s). It should be understood that the majority of the final film contains the desired multinary chalcogenide compound(s), yet a minority of the material might not be converted to the desired multinary chalcogenide compound(s).

As used herein, the terms “film” and “layer” will be understood to represent a portion of a stack. They will be understood to cover both a single layer as well as a multilayered structure (i.e., a nanolaminate). As used herein, these terms will be used synonymously and will be considered equivalent.

As used herein, the term “front electrode” refers to the electrode on the side of the absorber layer facing the incoming light.

As used herein, the term “back electrode” refers to the electrode on the side of the absorber layer facing away from the incoming light.

As used herein, “single grading,” “single-graded,” and “single gradient” will be understood to describe cases wherein a parameter varies throughout the thickness of a film or layer and further exhibits a monotonic variation. The variation is typically also continuous (not step-wise) and linear or nearly so. Examples of suitable parameters used herein that can be single-graded include the atomic concentration of a specific elemental species (i.e., composition variation) through the thickness of a film or layer, and bandgap energy variation through the thickness of a film or layer.

As used herein, “double grading,” “double-graded,” and “double gradient” will be understood to describe cases wherein a parameter varies throughout the thickness of a film or layer and further exhibits a variation wherein the value of the parameter is smaller toward the middle of the film or layer with respect to either end of the film or layer. It is not a requirement that the value of the parameter be equivalent at the two ends of the film or layer. Examples of suitable parameters used herein that can be double-graded include the atomic concentration of a specific elemental species (i.e., composition variation) through the thickness of a film or layer, and bandgap energy variation through the thickness of a film or layer.

As used herein, “substrate configuration” will be understood to describe cases wherein the TFPV stack is built sequentially on top of a substrate and the light is assumed to be incident upon the top of the TFPV stack. As used herein, an “n-substrate” configuration will be used to denote that the n-type layer (i.e. buffer layer) is closest to the incident light. The n-substrate configuration is the most common. As used herein, a “p-substrate” configuration will be used to denote that the p-type layer (i.e. absorber layer) is closest to the incident light.

As used herein, “superstrate configuration” will be understood to describe cases wherein the substrate faces the incident sunlight. The convention will be used wherein light is assumed to be incident upon the substrate. As used herein, an “n-superstrate” configuration will be used to denote that the n-type layer (i.e. buffer layer) is closest to the incident light. As used herein, a “p-superstrate” configuration will be used to denote that the p-type layer (i.e. absorber layer) is closest to the incident light.

As used herein, “substrate” will be understood to generally be one of float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, roll-to-roll processing, etc. in all of the methods and examples described herein.

As used herein, “precursor layer,” “precursor material,” “metal precursor layer,” “metal precursor material,” etc. will be understood to be equivalent and be understood to refer to a metal, metal alloy, metal chalcogenide, etc. layer and/or material that is first deposited and will ultimately become the absorber layer of the TFPV device after full chalcogenization and/or further processing.

As used herein, “optical absorber”, “absorber layer”, “absorber material”, etc. will be understood to be equivalent and be understood to refer to a layer and/or material that is responsible for the charge generation in the TFPV device after full chalcogenization and/or further processing.

As used herein, the notations “Al:ZnO” and “ZnO:Al” will be understood to be equivalent and will describe a material wherein the base material is the metal oxide and the element separated by the colon, “:”, is considered a dopant. In this example, Al is a dopant in a base material of zinc oxide. The notation is extendable to other materials and other elemental combinations.

As used herein, a “bandgap-grading element” will be understood to be a metal element that alters the bandgap when substituted for an element from the same periodic table Group in the absorber material. For example, substituting Ag for a portion of the Cu in a CIGS material will decrease the bandgap. For example, increasing the relative amount of Ga versus indium in a CIGS material will increase the bandgap. For example, substituting Se for a portion of the S in a Fe₂(Si,Ge)S₄ material will decrease the bandgap. For example, substituting Si for a portion of the Ge in a Fe₂GeS₄ material will increase the bandgap.

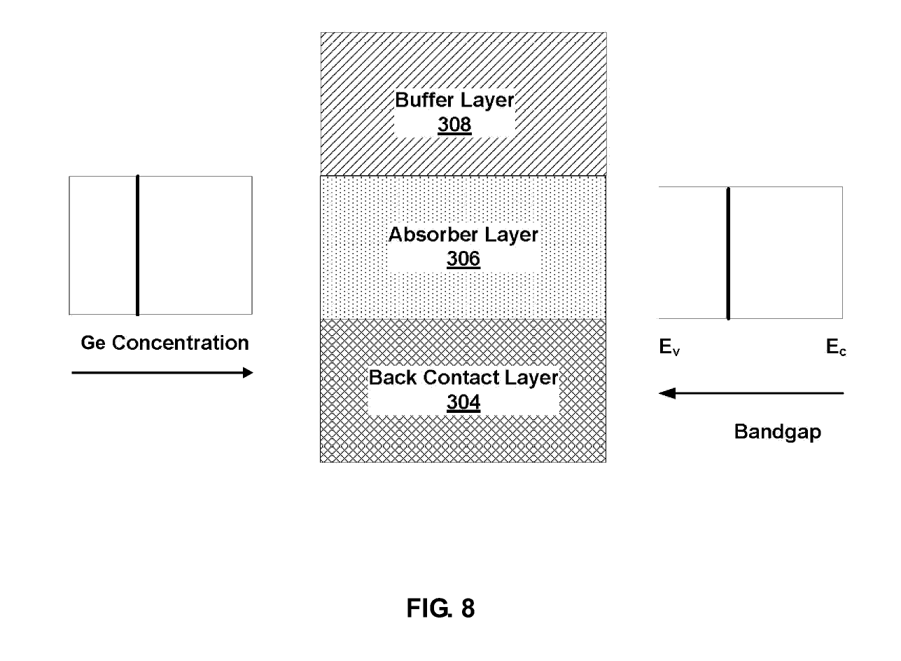

The bandgap value represents the energy difference between the top of the valence band and the bottom of the conduction band in the absorber layer. In FIGS. 8-11, the bandgap diagrams are included to aid the reader in visualizing the relative magnitude of the bandgap across the absorber layer. No inferences should be made with respect to absolute values or actual changes in either the valance band or conduction band values. The diagrams are for visualization purposes only. In various figures below, a TFPV material stack is illustrated using a simple planar structure. Those skilled in the art will appreciate that the description and teachings to follow can be readily applied to any simple or complex TFPV solar cell structure, (e.g. a stack with (non-conformal non-planar layers for optimized photon management). The drawings are for illustrative purposes only and do not limit the application of the present invention.

“Double grading” the bandgap of an absorber is a method known in the art to increase the efficiency of solar cells. In an absorber layer that has a double-graded bandgap profile, the bandgap of the layer increases toward the front surface and toward the back surface of the layer, with a bandgap minimum located in a center region of the layer. Double grading helps in reducing unwanted charge carrier recombination. The increasing bandgap profile at the back surface of the layer, (i.e., the absorber surface that is remote from the incident light in the substrate configuration), creates a back surface field, which reduces recombination at the back surface and enhances carrier collection. Generally, in the disclosure to follow, the description will apply to the “n-substrate” configuration for economy of language. However, those skilled in the art will understand that the disclosure is also equally applicable to either of the “p-substrate” or “n, p-superstrate” configurations discussed previously.

Embodiments of the present invention provide methods of forming Fe₂(Si,Ge)(S,Se)₄ layers suitable for use as absorber layers in solar cells. In some embodiments, the bandgap can be in the range from about 1.0 eV to about 1.6 eV and can be graded across the thickness by varying the relative amounts of Si and Ge and/or the relative amounts of S and Se in the finished layer. The Fe, Si, and Ge can be deposited from targets containing one or more of the elements, optionally with S and/or Se also included. Reactive sputtering in an atmosphere comprising S and/or Se (typically in the form of H₂S and/or H₂Se) can also be used to incorporate S and/or Se into the layer. Typically, complete sulfurization/selenization can be achieved by further heating in an H₂S and/or H₂Se atmosphere until no more S or Se can react with the layer. The heating can be at a temperature of 20-1000° C., typically 200-400° C.

The efficiency of thin-film photovoltaic (TFPV) devices depends on many properties of the absorber layer and the buffer layer such as crystallinity, grain size, composition uniformity, density, defect concentration, doping level, surface roughness, etc. The manufacture of TFPV devices entails the integration and sequencing of many unit processing steps. As an example, TFPV manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as TFPV devices. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC™) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching, texturing, polishing, cleaning, etc. HPC processing techniques have also been successfully adapted to deposition processes such as sputtering, atomic layer deposition (ALD), and chemical vapor deposition (CVD).

HPC processing techniques have been adapted to the development and investigation of absorber layers and buffer layers for TFPV solar cells as described in U.S. application Ser. No. 13/236,430 filed on Sep. 19, 2011, entitled “COMBINATORIAL METHODS FOR DEVELOPING SUPERSTRATE THIN FILM SOLAR CELLS” and is incorporated herein by reference. However, HPC processing techniques have not been successfully adapted to the development of contact structures for TFPV devices. Generally, there are two basic configurations for TFPV devices. The first configuration is known as a “substrate” configuration. In this configuration, the contact that is formed on or near the substrate is called the back contact. In this configuration, the light is incident on the TFPV device from the top of the material stack (i.e. the side opposite the substrate). CIGS TFPV devices are most commonly manufactured in this configuration. The second configuration is known as a “superstrate” configuration. In this configuration, the contact that is formed on or near the substrate is called the front contact. In this configuration, the light is incident on the TFPV device through the substrate. CdTe, and a-Si, TFPV devices are most commonly manufactured in this configuration. In both configurations, light trapping schemes may be implemented in the contact layer that is formed on or near the substrate. Additionally, other efficiency or durability improvements can be implemented in the contact layer that is formed farthest away from the substrate.

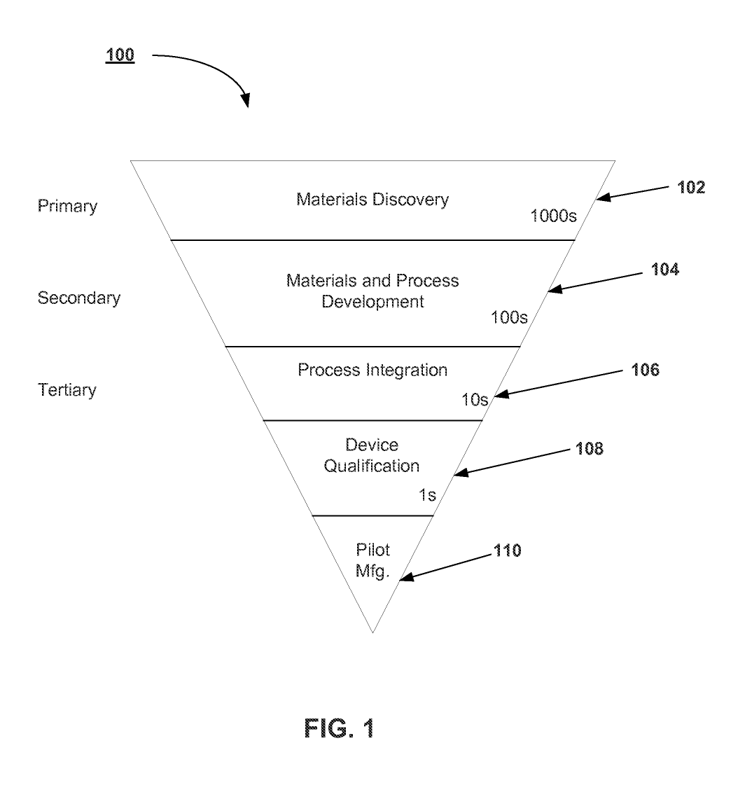

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of TFPV manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a TFPV device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture a TFPV device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the TFPV device. For example, such structures may include, but would not be limited to, contact layers, buffer layers, absorber layers, or any other series of layers or unit processes that create an intermediate structure found on TFPV devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

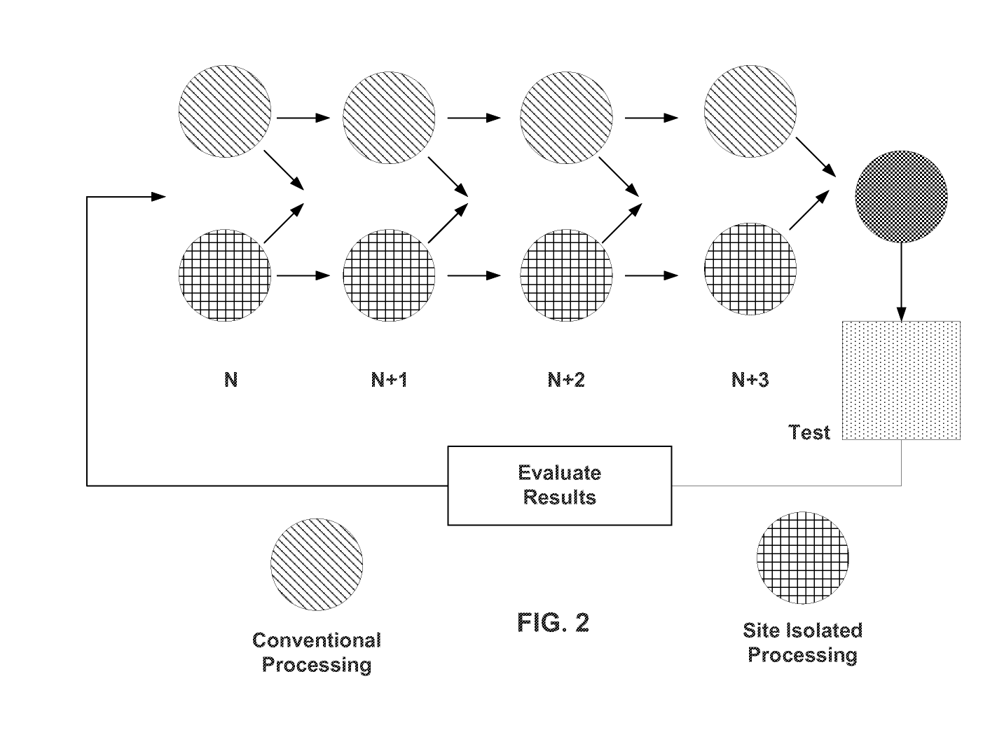

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. The combinatorial processing may employ uniform processing of site isolated regions or may employ gradient techniques. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in TFPV manufacturing may be varied.

As mentioned above, within a region, the process conditions are substantially uniform. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. However, in some embodiments, the processing may result in a gradient within the regions. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

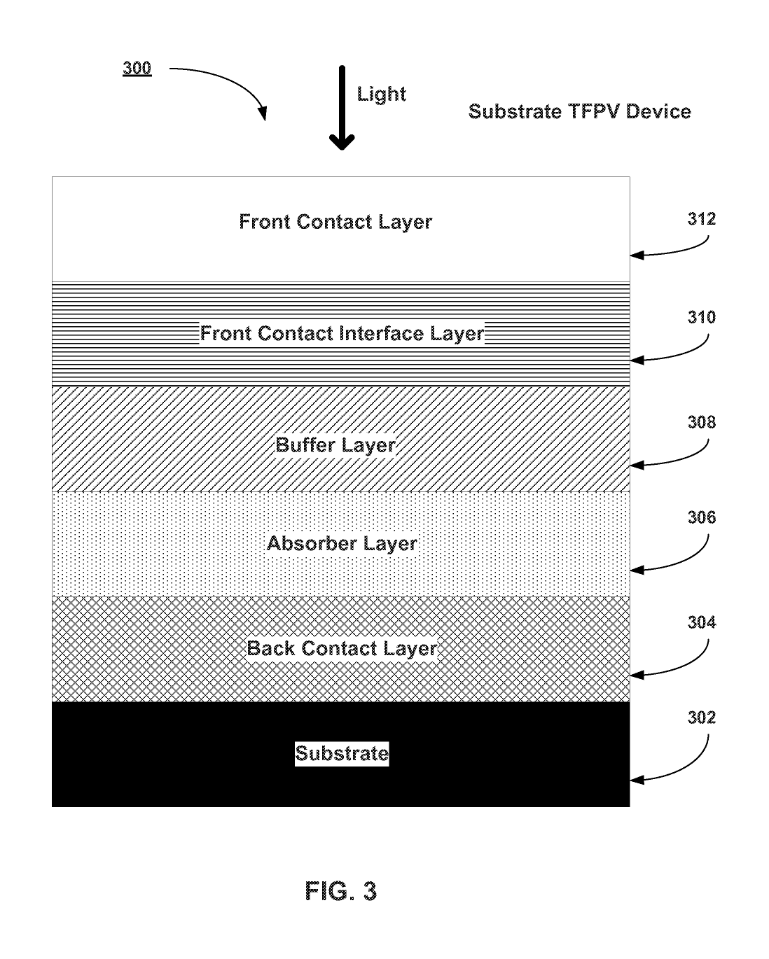

FIG. 3 illustrates a schematic diagram of a simple TFPV device stack in the substrate configuration consistent with some embodiments of the present invention. The convention will be used wherein light is assumed to be incident upon the top of the material stack in the substrate configuration as illustrated. This generic diagram would be typical of a TFPV device having a multinary optical absorber. A back contact layer, 304, is formed on a substrate, 302. Examples of suitable substrates comprise float glass, low-iron glass, borosilicate glass, flexible glass, specialty glass for high temperature processing, stainless steel, carbon steel, aluminum, copper, titanium, molybdenum, polyimide, plastics, cladded metal foils, etc. Furthermore, the substrates may be processed in many configurations such as single substrate processing, multiple substrate batch processing, in-line continuous processing, roll-to-roll processing, etc. As used herein, the phrase “back contact” will be understood to be the primary current conductor layer situated between the substrate and the absorber layer in a substrate configuration TFPV device. An example of a common back contact layer material is Mo. Other types of TFPV devices use different materials for the back contact. As an example, Cu alloys such as Cu/Au, Cu/graphite, Cu/Mo, Cu:ZnTe, etc. are typically used for CdTe TFPV devices and transparent conductive oxide (TCO) materials such as ZnO, ITO, SnO₂:F, etc. are typically used for a-Si TFPV devices. The back contact layer may be formed by any number of deposition technologies. Examples of suitable deposition technologies comprise physical vapor deposition (PVD) (e.g. sputtering), evaporation, chemical vapor deposition (CVD), atomic layer deposition (ALD), plating, printing, wet coating, etc. The thickness of the back contact layer is typically between about 0.3 μm and about 1.0 μm. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others.

Optionally, a diffusion barrier and/or adhesion-promotion layer (not shown) may be formed between the substrate and the back contact layer. When implemented, the diffusion barrier layer stops the diffusion of impurities from the substrate into the back contact layer, or alternatively, stops the diffusion and reaction of the back contact material with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. The diffusion barrier layer may be formed, partially or completely, from any well known technique such as sputtering, ALD, CVD, evaporation, wet methods such as printing or spraying of inks, screen printing, inkjet printing, slot die coating, gravure printing, wet chemical depositions, or from sol-gel methods, such as the coating, drying, and firing of polysilazanes.

A p-type absorber layer, 306, of, for example, Fe₂(Si,Ge)(S,Se)₄ is then deposited on top of the back contact layer. The absorber layer may be formed, partially or completely, using a variety of techniques such as PVD (sputtering), co-evaporation, in-line evaporation, plating, printing or spraying of inks, screen printing, inkjet printing, slot die coating, gravure printing, wet chemical depositions, CVD, etc. Advantageously, a small amount of Na is present during the absorber growth. The Na may be purposely added in the form of Na₂Se or another Na source, prior, during, or after the deposition and/or growth of the absorber layer. The absorber layer can be formed by depositing a multicomponent metal precursor film comprising Fe, Si, and Ge, for example, by using elemental targets, followed by chalcogenizing the layer, typically with sulfur (sulfurizing) or selenium (selenizing). The absorber layer can also be formed by depositing a multicomponent semiconductor film comprising Fe₂(Si,Ge)(S,Se)₄, for example, by using Fe₂(Si,Ge)(S,Se)₄ targets, followed by chalcogenizing the layer, typically with sulfur (sulfurizing) or selenium (selenizing). Optionally, the precursor and/or absorber layer undergoes a sulfurization or selenization process after formation to convert the precursor layer into a high-quality semiconductor film. The sulfurization or selenization process involves the exposure of the precursor and/or absorber layer to H₂Se, H₂S, Se vapor, S vapor, or diethylselenide (DESe) at temperatures most typically between about 100° C. and 600° C.

It should be noted that the precursor layers may already contain a chalcogen source (e.g. S), either as a separate layer, or incorporated into the bulk of the precursor layer. The precursor film can be a stack of layers, or one layer. The precursor layer can be dense, or porous. The precursor film typically contains Fe, Si, and Ge. The precursor layer can be deposited by sputtering from e.g., elemental sputter targets. Binary and multinary sputter targets such as SiS₂, GeS, or Fe₂SiSe₄, are utilized in some embodiments. In addition, plating and printing to deposit the metal precursor film containing Fe, Si, and/or Ge can be used as well. During the selenization process, a layer of Mo(S,Se)₂ (not shown) forms at the back contact/absorber layer interface and forms a fairly good ohmic contact between the two layers. Alternatively, a layer of Mo(S,Se)₂ (not shown) can be deposited at the back contact/absorber layer interface using a variety of well known techniques such as PVD (sputtering), CBD, ALD, plating, etc. The thickness of the layer can be from about 1 to about 10 microns. In some embodiments, the thickness of the layer can be from about 1 micron to about 3 microns. The performance of the absorber layer is sensitive to materials properties such as crystallinity, grain size, surface roughness, composition, defect concentration, etc. as well as processing parameters such as temperature, deposition rate, thermal treatments, etc.

An n-type buffer layer, 308, is then deposited on top of the absorber layer. Examples of suitable n-type buffer layers comprise CdS, ZnS, In₂S₃, In₂(S,Se)₃, CdZnS, ZnO, Zn(O,S), (Zn,Mg)O, etc. CdS is the material most often used as the n-type buffer layer with multinary optical absorbers. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between about 30 nm and about 100 nm. The performance of the buffer layer is sensitive to materials properties such as crystallinity, grain size, surface roughness, composition, defect concentration, etc. as well as processing parameters such as temperature, deposition rate, thermal treatments, etc.

Optionally, an intrinsic ZnO (iZnO) layer, 310, is then formed on top of the buffer layer. The iZnO layer is a high resistivity material and forms part of the transparent conductive oxide (TCO) stack that serves as part of the front contact structure. The TCO stack is formed from transparent conductive metal oxide materials and collects charge across the face of the TFPV solar cell and conducts the charge to tabs used to connect the solar cell to external loads. The iZnO layer makes the TFPV solar cell less sensitive to lateral non-uniformities caused by differences in composition or defect concentration in the absorber and/or buffer layers. The iZnO layer is typically between about 0 nm and 150 nm in thickness. The iZnO layer is typically formed using a (reactive) PVD (sputtering) technique or CVD technique, but can be deposited by plating or printing as well. A low resistivity top TCO layer, 312, (examples include Al:ZnO (AZO), InSnO (ITO), InZnO, B:ZnO, Ga:ZnO, F:ZnO, F:SnO₂, etc.) is formed on top of the iZnO layer. The top TCO layer is typically between about 0.25 μm and 1.0 μm in thickness. The top TCO layer is typically formed using a (reactive) PVD (sputtering) technique or CVD technique. Optionally, the transparent top electrode can be printed or wet-coated from (silver) nano-wires, carbon nanotubes, and the like.

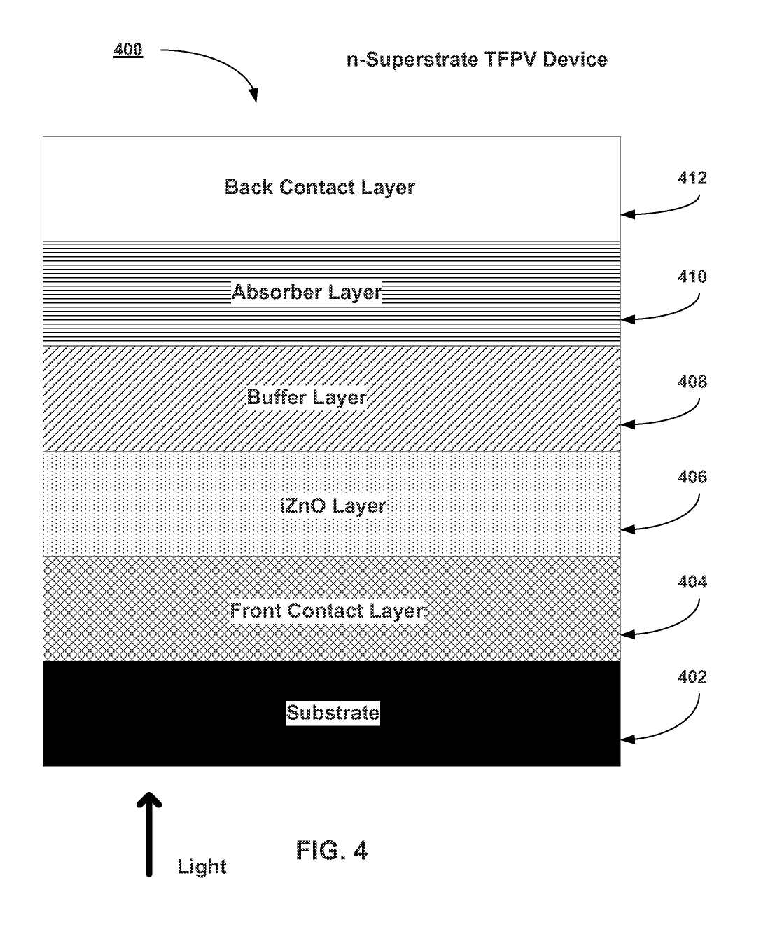

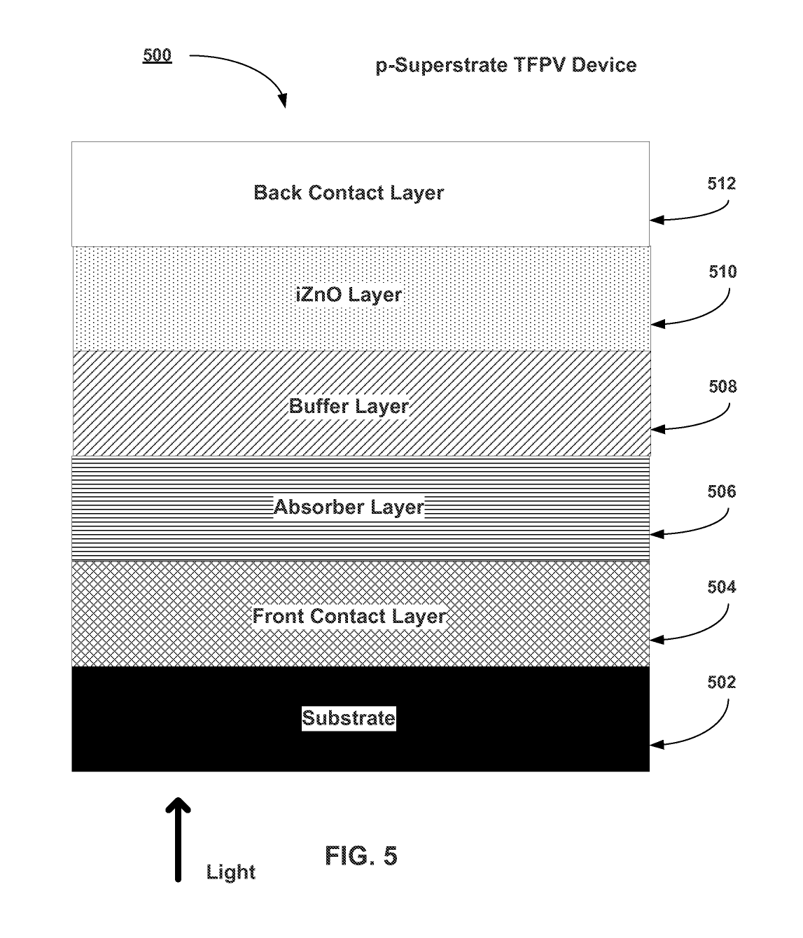

FIG. 4 illustrates a simple TFPV device material stack, 400, consistent with some embodiments of the present invention. The TFPV device illustrated in FIG. 4 is shown in a superstrate configuration wherein the glass substrate faces the incident sunlight. The convention will be used wherein light is assumed to be incident upon the substrate and material stack as illustrated. As used herein, this configuration will be labeled an “n-superstrate” configuration to denote that the n-type layer (i.e., buffer layer) is closest to the incident light. This label is to distinguish the configuration from an alternate configuration described with respect to FIG. 5 below. The formation of the TFPV device will be described starting with the substrate. Examples of suitable substrates comprise float glass, low-iron glass, borosilicate glass, flexible glass, specialty glass for high temperature processing, polyimide, plastics, etc. Furthermore, the substrates may be processed in many configurations such as single substrate processing, multiple substrate batch processing, in-line continuous processing, roll-to-roll processing, etc.

A low resistivity bottom TCO front contact layer, 404, (examples include Al:ZnO (AZO), InSnO (ITO), InZnO, B:ZnO, Ga:ZnO, F:ZnO, F:SnO₂, etc.) is formed on top of the substrate, 402. As used herein, the phrase “front contact” will be understood to be the primary current conductor layer situated between the substrate and the buffer layer in a superstrate configuration TFPV device. The bottom TCO layer is typically between about 0.3 μm and 2.0 μm in thickness. The bottom TCO layer is typically formed using a reactive PVD (sputtering) technique or CVD technique.

Optionally, a diffusion barrier and/or adhesion-promotion layer (not shown) may be formed between the substrate, 402, and the front contact layer, 404. When implemented, the diffusion barrier layer stops the diffusion of impurities from the substrate into the TCO, or alternatively, stops the diffusion and reaction of the TCO material and above layers with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. It should be understood that the diffusion barrier layer composition and thickness are optimized for optical transparency as necessary for the superstrate configuration. The diffusion barrier layer may be formed from any well known technique such as sputtering, ALD, CVD, evaporation, wet methods such as printing or spraying of inks, screen printing, inkjet printing, slot die coating, gravure printing, wet chemical depositions, or from sol-gel methods, such as the coating, drying, and firing of polysilazanes.

An intrinsic iZnO layer, 406, is then formed on top of the TCO layer. The iZnO layer is a high resistivity material and forms part of the transparent conductive oxide (TCO) stack that serves as part of the front contact structure. The iZnO layer makes the TFPV device less sensitive to lateral non-uniformities caused by differences in composition or defect concentration in the absorber and/or buffer layers. The iZnO layer is typically between about 0 nm and 150 nm in thickness. The iZnO layer is typically formed using a reactive PVD (sputtering) technique or CVD technique.

An n-type buffer layer, 408, is then deposited on top of the iZnO layer, 406. Examples of suitable n-type buffer layers comprise CdS, ZnS, In₂S₃, In₂(S,Se)₃, CdZnS, ZnO, Zn(O,S), (Zn,Mg)O, etc. CdS is the material most often used as the n-type buffer layer with multinary optical absorbers. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between about 30 nm and about 100 nm. The performance of the buffer layer is sensitive to materials properties such as crystallinity, grain size, surface roughness, composition, defect concentration, etc. as well as processing parameters such as temperature, deposition rate, thermal treatments, etc.

A p-type absorber layer, 410, of for example, Fe₂(Si,Ge)(S,Se)₄ is then deposited on top of the buffer layer. The absorber layer may be formed, partially or completely, using a variety of techniques such as PVD (sputtering), co-evaporation, in-line evaporation, plating, printing or spraying of inks, screen printing, inkjet printing, slot die coating, gravure printing, wet chemical depositions, CVD, etc. Advantageously, a small amount of Na is present during the growth of the absorber. The Na may be purposely added in the form of Na₂Se or another Na source, prior, during, or after the deposition and/or growth of the absorber layer. The absorber layer can be formed by depositing a multicomponent metal precursor film comprising Fe, Si, and Ge, for example, by using elemental targets, followed by chalcogenizing the layer, typically with sulfur (sulfurizing) or selenium (selenizing). The absorber layer can also be formed by depositing a multicomponent semiconductor film comprising Fe₂(Si,Ge)(S,Se)₄, for example, by using Fe₂(Si,Ge)(S,Se)₄ targets, followed by chalcogenizing the layer, typically with sulfur (sulfurizing) or selenium (selenizing). Optionally, the precursor and/or absorber layer undergoes a sulfurization or selenization process after formation to convert the precursor layer into a high-quality semiconductor film. The sulfurization or selenization process involves the exposure of the precursor and/or absorber layer to H₂Se, H₂S, Se vapor, S vapor, or diethylselenide (DESe) at temperatures most typically between about 100° C. and 600° C.

It should be noted that the precursor layer may already contain a chalcogen source (e.g. S), either as a separate layer, or incorporated into the bulk of the precursor layer. The precursor film can be a stack of layers, or one layer. The precursor layer can be dense, or porous. The precursor film typically contains Fe, Si, and Ge. The precursor layer can be deposited by sputtering from e.g., elemental sputter targets. Binary and multinary sputter targets such as SiS₂, GeS, or Fe₂SiSe₄, are utilized in some embodiments. In addition, plating and printing to deposit the metal precursor film containing Fe, Si, and/or Ge can be used as well. During subsequent processing, a layer of Mo(S,Se)₂ (not shown) is formed at the back contact/absorber layer interface and forms a fairly good ohmic contact between the two layers. The thickness of the layer can be from about 1 to about 10 microns. In some embodiments, the thickness of the layer can be from about 1 micron to about 3 microns. The performance of the absorber layer is sensitive to materials properties such as crystallinity, grain size, surface roughness, composition, defect concentration, etc. as well as processing parameters such as temperature, deposition rate, thermal treatments, etc.

A back contact layer, 412, is formed on absorber layer, 410. An example of a common back contact layer material is Mo. The back contact layer may be formed by any number of deposition technologies. Examples of suitable deposition technologies comprise PVD (sputtering), evaporation, chemical vapor deposition (CVD), atomic layer deposition (ALD), plating, etc. The thickness of the back contact layer is typically between about 0.3 μm and about 1.0 μm. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others. Other types of TFPV devices use different materials for the back contact. As an example, Cu alloys such as Cu/Au, Cu/graphite, Cu/Mo, Cu:ZnTe, etc. are typically used for CdTe TFPV devices and TCO materials such as ZnO, ITO, SnO₂:F, etc. are typically used for a-Si TFPV devices.

FIG. 5 illustrates a simple TFPV device material stack, 500, consistent with some embodiments of the present invention. The TFPV device illustrated in FIG. 5 is shown in a superstrate configuration wherein the glass substrate faces the incident sunlight. The convention will be used wherein light is assumed to be incident upon the substrate and material stack as illustrated. As used herein, this configuration will be labeled a “p-superstrate” configuration to denote that the p-type layer (i.e. absorber layer) is closest to the incident light. This label is to distinguish the configuration from the alternate configuration described with respect to FIG. 4 previously. The formation of the TFPV device will be described starting with the substrate. A similar structure and similar method would also be applicable to the formation of a TFPV solar cell fabricated with a superstrate configuration. Examples of suitable substrates comprise float glass, low-iron glass, borosilicate glass, flexible glass, specialty glass for high temperature processing, polyimide, plastics, etc. Furthermore, the substrates may be processed in many configurations such as single substrate processing, multiple substrate batch processing, in-line continuous processing, roll-to-roll processing, etc.

A low resistivity bottom TCO front contact layer (examples include Al:ZnO (AZO), InSnO (ITO), InZnO, B:ZnO, Ga:ZnO, F:ZnO, F:SnO₂, etc.), 504, is formed on top of the substrate, 502. As used herein, the phrase “front contact” will be understood to be the primary current conductor layer situated between the substrate and the absorber layer in a superstrate configuration TFPV device. The bottom TCO layer is typically between about 0.3 μm and 2.0 μm in thickness. The bottom TCO layer is typically formed using a reactive PVD (sputtering) technique or CVD technique. The TCO can be a p-type TCO, (e.g. ternary-based oxide in the family of Co₃O₄-based spinels, like Co₂ZnO₄ and Co₂NiO₄). Nevertheless, it should be understood that an n-type TCO with an additional layer (e.g., a heavily-doped p-type semiconductor layer, or MoSe₂) between the TCO and the absorber can be used as well. Furthermore, the TCO might be a bi- or multi-layer of an n-type TCO in contact with the substrate, followed by an ultrathin metal layer, (e.g. like Ag), followed by a thin p-type TCO in contact with the absorber layer, with/without an additional MoSe₂ layer between the p-type TCO and the absorber layer.

Optionally, a diffusion barrier and/or adhesion-promotion layer (not shown) may be formed between the substrate, 502, and the front contact layer 504. When implemented, the diffusion barrier and/or adhesion-promotion layer stops the diffusion of impurities from the substrate into the TCO, or alternatively, stops the diffusion and reaction of the TCO material and above layers with the substrate. Examples of common diffusion barrier and/or adhesion-promotion layers comprise chromium, vanadium, tungsten, nitrides such as tantalum nitride, tungsten nitride, titanium nitride, silicon nitride, zirconium nitride, hafnium nitride, oxy-nitrides such as tantalum oxy-nitride, tungsten oxy-nitride, titanium oxy-nitride, silicon oxy-nitride, zirconium oxy-nitride, hafnium oxy-nitride, oxides such as aluminum oxide, silicon oxide, carbides such as silicon carbide, binary and/or multinary compounds of tungsten, titanium, molybdenum, chromium, vanadium, tantalum, hafnium, zirconium, and/or niobium with/without the inclusion of nitrogen and/or oxygen. It should be understood that the diffusion barrier and/or adhesion-promotion layer composition and thickness are optimized for optical transparency as necessary for the superstrate configuration. The diffusion barrier and/or adhesion-promotion layer may be formed from any well known technique such as sputtering, ALD, CVD, evaporation, wet methods such as printing or spraying of inks, screen printing, inkjet printing, slot die coating, gravure printing, wet chemical depositions, or from sol-gel methods such as the coating, drying, and firing of polysilazanes.

A p-type absorber layer, 506, of for example, Fe₂(Si,Ge)(S,Se)₄ is then deposited on top of the buffer layer. The absorber layer may be formed, partially or completely, using a variety of techniques such as PVD (sputtering), co-evaporation, in-line evaporation, plating, printing or spraying of inks, screen printing, inkjet printing, slot die coating, gravure printing, wet chemical depositions, CVD, etc. Advantageously, a small amount of Na is present during the growth of the absorber. The Na may be purposely added in the form of Na₂Se or another Na source, prior, during, or after the deposition and/or growth of the absorber layer. The absorber layer can be formed by depositing a multicomponent metal precursor film comprising Fe, Si, and Ge, for example, by using elemental targets, followed by chalcogenizing the layer, typically with sulfur (sulfurizing) or selenium (selenizing). The absorber layer can also be formed by depositing a multicomponent semiconductor film comprising Fe₂(Si,Ge)(S,Se)₄, for example, by using Fe₂(Si,Ge)(S,Se)₄ targets, followed by chalcogenizing the layer, typically with sulfur (sulfurizing) or selenium (selenizing). Optionally, the precursor and/or absorber layer undergoes a sulfurization or selenization process after formation to convert the precursor layer into a high-quality semiconductor film. The sulfurization or selenization process involves the exposure of the precursor and/or absorber layer to H₂Se, H₂S, Se vapor, S vapor, or diethylselenide (DESe) at temperatures most typically between about 100° C. and 600° C.

It should be noted that the precursor layer may already contain a chalcogen source (e.g. S), either as a separate layer, or incorporated into the bulk of the precursor layer. The precursor film can be a stack of layers, or one layer. The precursor layer can be dense, or porous. The precursor film typically contains Fe, Si, and Ge. The precursor layer can be deposited by sputtering from e.g., elemental sputter targets. Binary and multinary sputter targets such as SiS₂, GeS, or Fe₂SiSe₄, are utilized in some embodiments. In addition, plating and printing to deposit the metal precursor film containing Fe, Si, and/or Ge can be used as well. During subsequent processing, a layer of Mo(S,Se)₂ (not shown) is formed at the back contact/absorber layer interface and forms a fairly good ohmic contact between the two layers. The thickness of the layer can be from about 1 to about 10 microns. In some embodiments, the thickness of the layer can be from about 1 micron to about 3 microns. The performance of the absorber layer is sensitive to materials properties such as crystallinity, grain size, surface roughness, composition, defect concentration, etc. as well as processing parameters such as temperature, deposition rate, thermal treatments, etc.

An n-type buffer layer, 508, is then deposited on top of the absorber layer. Examples of suitable n-type buffer layers comprise CdS, ZnS, In₂S₃, In₂(S,Se)₃, CdZnS, ZnO, Zn(O,S), (Zn,Mg)O, etc. CdS is the material most often used as the n-type buffer layer in mulinary TFPV devices. The buffer layer may be deposited using chemical bath deposition (CBD), chemical surface deposition (CSD), PVD (sputtering), printing, plating, ALD, Ion-Layer-Gas-Reaction (ILGAR), ultrasonic spraying, or evaporation. The thickness of the buffer layer is typically between about 30 nm and about 100 nm. The performance of the buffer layer is sensitive to materials properties such as crystallinity, grain size, surface roughness, composition, defect concentration, etc. as well as processing parameters such as temperature, deposition rate, thermal treatments, etc.

An intrinsic iZnO layer, 510, is then formed on top of the buffer layer. The iZnO layer is a high resistivity material and forms part of the back contact structure. The iZnO layer makes the TFPV device less sensitive to lateral non-uniformities caused by differences in composition or defect concentration in the absorber and/or buffer layers. The iZnO layer is typically between about 0 μm and 150 μm in thickness. The iZnO layer is typically formed using a reactive PVD (sputtering) technique or CVD technique.

A back contact layer, 512, is formed on intrinsic iZnO layer, 510. An example of a suitable back contact layer material is a thin n-type TCO followed by Ni and/or Al. The back contact layer may be formed by any number of deposition technologies. Examples of suitable deposition technologies comprise PVD (sputtering), evaporation, chemical vapor deposition (CVD), atomic layer deposition (ALD), plating, etc. The thickness of the back contact layer is typically between about 0.3 μm and about 1.0 μm. The back contact layer has a number of requirements such as high conductivity, good ohmic contact to the absorber layer, ease of bonding to tabs for external connectivity, ease of scribing or other removal, good thermo-mechanical stability, and chemical resistance during subsequent processing, among others. Other types of TFPV devices use different materials for the back contact. As an example, Cu alloys such as Cu/Au, Cu/graphite, Cu/Mo, Cu:ZnTe, etc. are typically used for CdTe TFPV devices and TCO materials such as ZnO, ITO, SnO₂:F, etc. are typically used for a-Si TFPV devices.

The film stack described above is just one example of a film stack that can be used for TFPV devices. As an example, another substrate film stack (i.e. similar configuration as FIG. 3) might be: substrate/AZO/Mo/Fe₂(Si,Ge)Se₄/CdS/iZnO/AZO. As an example, another p-superstrate film stack (i.e. similar configuration as FIG. 5) might be: substrate/barrier/ZnO:Al/Mo/Fe₂(Si,Ge)Se₄/CdS/iZnO/ZnO:Al/Al. The detailed film stack configuration is not meant to be limiting, but simply serves as an example of the implementation of embodiments of the present invention.

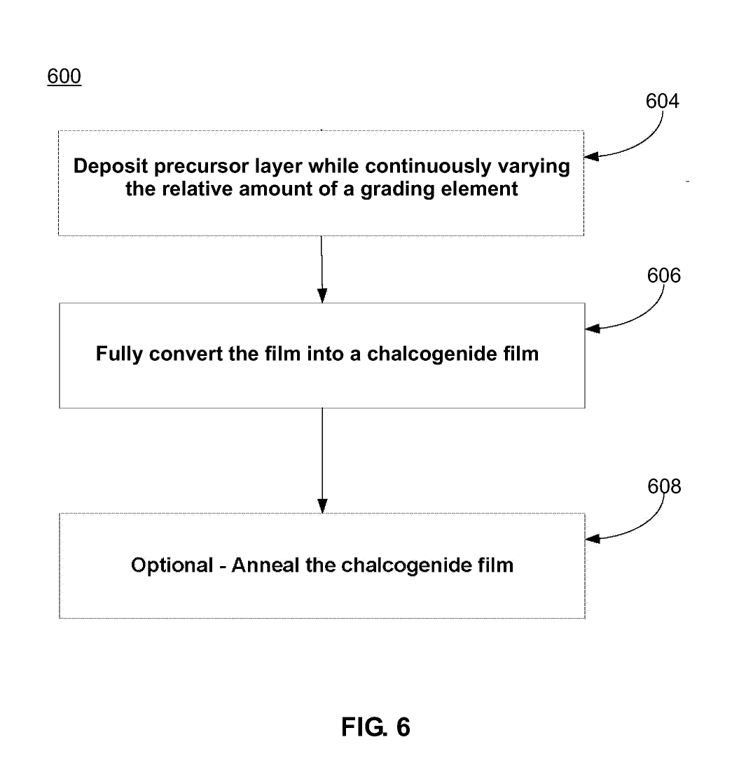

The formation of the absorber layer is typically a multi-step process. One way of bandgap grading absorber materials is by a 2-step approach as illustrated in FIG. 6. For a continuously variable bandgap gradient, the absorber materials can be deposited by continuously varying the composition of the deposited material. In step 604, precursor layer is deposited, using a plurality of absorber materials to provide a varying composition. For Fe₂(Si,Ge)(S,Se)₄ absorbers, the precursor layer comprises Fe, Si, and Ge. The bandgap grading is accomplished by varying the gradient of the composition. For example, substitution of Ge for Si decreases the bandgap.

The precursor layer needs to be converted to one or more chalcogenide compound(s) to form the absorber layer. The precursor layer is converted to one or more chalcogenide compound(s) by heating the film in the presence of a source of one or more Group-VIA elements as indicated in step 606. The chalcogenization process can include both selenization and sulfurization, meaning the final absorber (Fe₂(Si,Ge)(S,Se)₄) contains both selenium and sulfur. Choice of sulfurization or selenization also affects the bandgap of the absorber material. Optionally, the chalcogenide film can be annealed as indicated in step 608.

Generally, the 2-step method may comprise more than two steps when various wet chemical and/or conversion methods (e.g. for densification or contaminant removal) and/or deposition steps (e.g. for a separate chalcogen layer as discussed previously) are used to form the metal precursor film. The metal-containing film may be dense or porous.

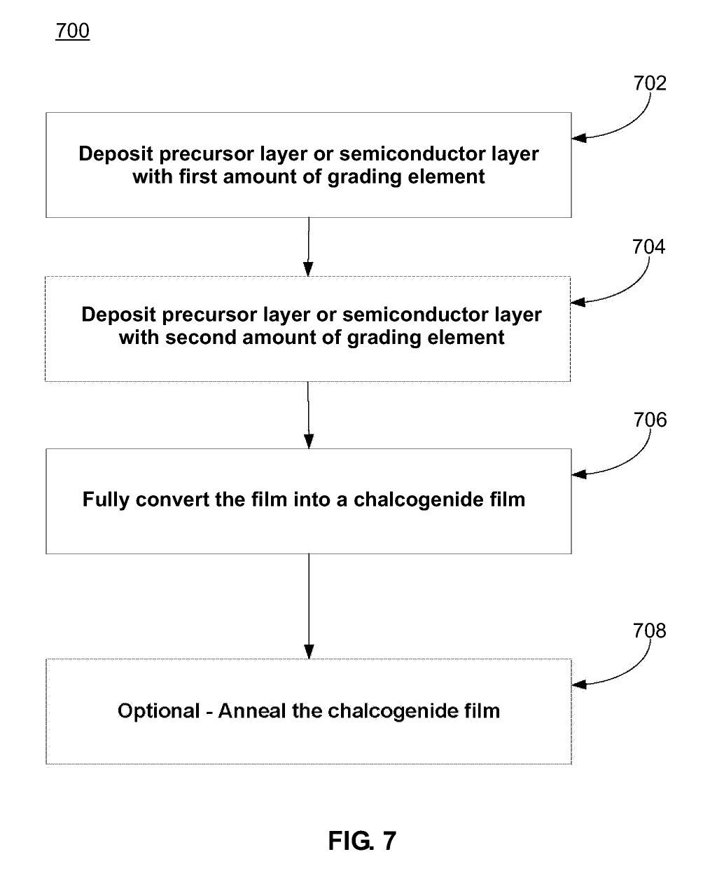

A second way of grading absorbers is by a 3-step approach as illustrated in FIG. 7. In step 702, a precursor layer is deposited. The precursor layer can include Fe, Si, and Ge. The precursor layer can also be bandgap-tuned. For example, substitution of Ge for Si decreases the bandgap.

In step 704, one or more additional precursor layers are deposited. These layers generally will have a different amount of a grading element such as Ge so that the bandgap of the finished semiconductor is different from the bandgap of the semiconductor formed from the precursor layer deposited in step 702. In this method, the bandgap grading is accomplished by varying the composition between the two layers (or among a plurality of layers).

The precursor layer needs to be converted to a chalcogenide to form the absorber layer. In step 706, the entire precursor stack to form the final absorber is converted using a chalcogenization process. The precursor layer is converted to one or more chalcogenide compound(s) by heating the film in the presence of a source of one or more Group-VIA elements as indicated in step 606. The chalcogenization process can include both selenization and sulfurization, meaning the final absorber (Fe₂(Si,Ge)(S,Se)₄) contains both selenium and sulfur. Choice of sulfurization or selenization also affects the bandgap of the absorber material. In addition, the chalcogenization step can be performed after the first precursor layer is deposited, and again after the second precursor layer is deposited, if desired. The chalcogenization process may include an additional anneal step at the end to improve the device performance as illustrated in step 710. The annealing can improve the crystal quality, grain size, and compositional uniformity of the absorber layer as well as resulting performance characteristics such as optical or electrical performance parameters. Such improvements can be characterized by a variety of measurement methods including X-ray diffraction, scanning electron microscopy, secondary ion mass spectrometry, and photoluminescence. Details of a chalcogenization process including an additional anneal step are described in U.S. patent application Ser. No. 13/283,225, entitled “Method of Fabricating CIGS by Selenization at High Temperatures”, filed on Oct. 27, 2011, which is herein incorporated by reference.

Generally, the 3-step method may comprise more than 3 steps when various wet chemical and/or conversion methods (e.g., for densification or contaminant removal) and/or deposition steps are used to form the metal precursor film and/or the metal rich layer. As discussed above, the metal precursor film and/or the metal rich layer may each be a single layer or may each be formed from multiple layers, it may be dense or porous.

In each of the multi-step methods described herein, the performance of the absorber layer can be improved by incorporating a small amount (i.e. about 0.1 atomic %) of Na prior, during, or after the growth of the absorber layer. The incorporation of Na results in improved film morphology, higher conductivity, and beneficial changes in the defect distribution within the absorber material. The Na may be introduced in a number of ways. The Na may diffuse out of the glass substrate, out of a layer disposed between the glass substrate and the back contact (e.g., a Na containing sol-gel layer formed under the back contact), or out of the back contact (e.g., molybdenum doped with a Na salt). The Na may be introduced from a separate Na containing layer formed on top of the back contact. The Na may be introduced by incorporating a Na source in the Fe(Si, Ge) precursor film. Examples of suitable Na sources comprise Na₂Se, Na₂O₂, NaF, Na₂S, etc. The Na may be introduced from a separate Na containing layer formed on top of the Fe(Si, Ge) precursor film. The Na may be introduced from a separate Na containing layer formed on top of the partially or completely chalcogenized Fe₂(Si,Ge)(S,Se)₄ film. The Na may be introduced by incorporating a Na source during the selenization step. The Na may be introduced after the final selenization step, followed by a heat treatment. The Na may be introduced by combining any of these methods as required to improve the performance of the absorber layer. It should be noted that similar Group IA, and/or Group IIA elements like K, and Ca can be used instead of sodium.

In each of the multi-step methods described above, a metal precursor film(s) can be deposited, a semiconductor material can be deposited, or a combination of metal and semiconductor can be deposited. For example, the metal precursor film can be deposited using PVD from elemental targets. The semiconductor material can be deposited using PVD from binary and multinary targets. For example, targets comprising binary targets such as FeₓS_{y}, SiₓS_{y}, GeₓS_{y}, FeₓSe_{y}, SiₓSe_{y}, GeₓSe_{y}, or multinary targets such as FeₓSi_{y}Ge_{z}Sᵥ, FeₓSi_{y}Ge_{z}Seᵥ, or FeₓSi_{y}Ge_{z}S_{w}Seᵥ, where the values of x, y, z, w and v can vary, can be utilized. The binary and multinary targets can comprise stoichiometric or non-stoichiometric compounds as well as mixtures and alloys. Non-stoichiometric compounds can be used to the extent that the compounds can be made; if a particular atomic ratio is unstable the resulting target may be a mixture or alloy. A combination of PVD targets can be used to prepare metal precursor or metal-containing films having varying compositions and varying bandgap.

In some embodiments, each elemental target comprises Fe, Si, or Ge. In some embodiments, the PVD comprises reactive sputtering in an atmosphere comprising one or more of S or Se.

In some embodiments, each binary target comprises compounds comprising FeS₂, FeSe₂, FeSi, FeGe, SiS₂, SiSe, SiGe, GeS₂ or GeSe. In addition, targets comprising mixtures can be made with arbitrary composition ratios, by, for example, sintering arbitrary ratios of mixed elemental powders. For example, targets comprising FeₓS_{y} can be prepared, where x≦y≦2x. In some embodiments, each binary target comprises mixtures or alloys comprising Fe and S, Fe and Se, Fe and Si, Fe and Ge, Si and S, Si and Se, Si and Ge, Ge and S, or Ge and Se. In particular, binary targets of the following composition can be used: FeₓS_{y}, where x=0.3-0.5, y=(1−x) (includes FeS, FeS₂, Fe₂S₃); SiₓS_{y}, where x=0.2-0.4 (includes SiS₂); GeₓS_{y}, where x=0.2-0.4 (includes GeS₂); FeₓSe_{y}, where x=0.2-0.4 (includes FeSe₂); SiₓSe_{y}, where x=0.2-0.4 (includes SiSe₂); and GeₓSe_{y}, where x=0.4-0.6 (includes GeSe). Binary targets comprising additional possible constituents useful for grading the bandgap can also be utilized. For example, targets comprising Fe and Te, Pb and Te, Sn and Te, Si and C, or Ge and Te can be used in the preparation of bandgap graded layers. In some embodiments, the binary targets are used for PVD comprising reactive sputtering in an atmosphere comprising one or more of S or Se.

In some embodiments, each ternary target comprises a ternary compound comprising Fe₂SiS₄, Fe₂GeS₄, Fe₂SiSe₄, or Fe₂GeSe₄. In some embodiments each ternary target comprises mixtures or alloys comprising Fe, Si, and S; Fe, Si, and Se; Fe, Ge, and S; Fe, Ge, and Se; Fe, Si and Ge, Si, Ge and S, Si, Ge and Se. Targets comprising mixtures can be made with arbitrary composition ratios, by, for example, sintering arbitrary ratios of mixed elemental powders. Ternary targets comprising additional possible constituents useful for grading the bandgap can also be utilized. For example, targets comprising Fe, Si and Te; Fe, Ge and Te; Sn, Pb and Te; Si, Sn and Te; Si, C and S, or Si, Ge and Te, and the like, can be used in the preparation of bandgap graded layers. In some embodiments, the ternary targets are used for PVD comprising reactive sputtering in an atmosphere comprising one or more of S or Se.

In some embodiments, each quaternary target comprises Fe₂(Si,Ge)S₄, Fe₂(Si,Ge)Se₄, Fe₂Si(S,Se)₄, or Fe₂Ge(S,Se)₄. In some embodiments, each quaternary target comprises mixtures or alloys comprising Fe, Si, Ge, and S; Fe, Si, Ge, and Se; Fe, Si, S and Se; or Fe, Ge, S and Se. Targets comprising mixtures can be made with arbitrary composition ratios, by, for example, sintering arbitrary ratios of mixed elemental powders. Quaternary targets comprising additional possible constituents useful for grading the bandgap can also be utilized. For example, targets comprising Fe, Si, Ge and Te; Fe, Ge, Sn and Te; Fe, Sn, Pb and Te; Si, Ge, Sn and Te; Si, C, Sn and S, or Si, Ge, Pb and Te, and the like, can be used in the preparation of bandgap graded layers. In some embodiments, the quaternary targets are used for PVD comprising reactive sputtering in an atmosphere comprising one or more of S or Se.

In some embodiments, each quinternary target comprises Fe₂(Si,Ge)(S,Se)₄, with varying amounts of at least one of Si or Ge and S or Se in different quinternary targets. In particular, quinternary targets can be utilized where the target comprises FeₓSi_{y}Ge_{z}S_{w}Seᵥ, where x=0.26-0.31, y=0-0.17, z=0-0.17, w=0-0.5, and v=0-0.5 (includes e.g., Fe₂SiS₄ and Fe₂GeS₄). In some embodiments each quinternary target comprises mixtures or alloys comprising Fe, Si, Ge, and S and Se. Targets comprising mixtures can be made with arbitrary composition ratios, by for example, sintering arbitrary ratios of mixed elemental powders. Quinternary targets comprising additional possible constituents useful for grading the bandgap can also be utilized. For example, targets comprising Fe, C, Si, Sn and Te; Fe, Si, Ge, Sn and Te; Fe, Si, Sn, Pb and S; and the like can be used in the preparation of bandgap graded layers. In some embodiments, the quinternary target is used for PVD comprising reactive sputtering in an atmosphere comprising one or more of S or Se.

In some embodiments, three elemental targets are used, one comprising Fe, one comprising Si, and one comprising Ge. These targets can be used in an inert gas atmosphere. In some embodiments, reactive sputtering can be used where the atmosphere comprises S and/or Se (typically in the form of H₂S and/or H₂Se). The substrate temperature can be in the range 20-1000° C., typically 200-400° C. After deposition, whether in an inert or reactive atmosphere, additional sulfurization and/or selenization can be performed in a batch or inline furnace by further heating in an H₂S and/or H₂Se atmosphere until no more S or Se can react with the layer. The heating can be at a temperature of 20-1000° C., typically 200-400° C.

In some embodiments, three binary targets are used, one comprising one or more of FeₓS_{y} (x≦y≦2x) and FeSe₂, one comprising one or more of SiS₂ and SiSe, and a third comprising one or more of GeS₂ and GeSe. Note that compounds of Fe and S exist in nature in at least seven stable forms (listed in order of increasing stability): Iron(II) sulfide (FeS, the less stable amorphous form), Troilite (FeS), Greigite (Fe₃S₄, analog to magnetite, Fe₃O₄), Pyrrhotite Fe₁₋ₓS (where x=0 to 0.2, or Fe₇S₈), Mackinawite, Fe₁₊ₓS (where x=0 to 0.1), Marcasite or iron(II) disulfide (FeS₂ [orthorhombic]), Pyrite or iron(II) disulfide (FeS₂ [cubic]). These targets can be used in an inert gas atmosphere. In some embodiments, reactive sputtering can be used where the atmosphere comprises S and/or Se (typically in the form of H₂S and/or H₂Se). The substrate temperature can be in the range 20-1000° C., typically 200-400° C. After deposition, whether in an inert or reactive atmosphere, additional sulfurization and/or selenization can be performed in a batch or inline furnace by further heating in an H₂S and/or H₂Se atmosphere until no more S or Se can react with the layer. The heating can be at a temperature of 20-1000° C., typically 200-400° C.

In some embodiments, targets can be used comprising one or more of Fe₂SiS₄, Fe₂GeS₄, Fe₂SiSe₄, and Fe₂GeSe₄. While in principle, these targets can comprise substantially the same elements in the same proportions as the intended absorber layer to be deposited, the layer as deposited may not be fully sulfurized and/or selenized. Accordingly, reactive sputtering and/or additional sulfurization/selenization can be performed as described above for layers formed by sputtering from elemental and binary targets.

Typically, the precursor material will deviate in shape, size, composition, homogeneity, crystallinity, or some combination of these parameters from the absorber material that is ultimately formed as a result of the method. As mentioned previously, the metal precursor film(s) can comprise multiple layers. These layers may be deposited by the same or by different deposition techniques. These layers can be porous, or dense.

The metal precursor film(s) can be deposited using a number of techniques. Examples comprise dry deposition techniques such as batch or in-line (co)evaporation, batch or in-line PVD (sputtering), ALD, CVD, Plasma enhanced CVD (PECVD), Plasma enhanced ALD (PEALD), atmospheric pressure CVD (APCVD), ultra-fast atmospheric ALD, etc.

Examples of other techniques that can be used to deposit the metal precursor materials comprise ion-layer-gas-reaction (ILGAR), hot liquid metal deposition, sol-gel techniques, metal emulsions, electroplating, electroless plating, chemical bath deposition (CBD), and chemical surface deposition (CSD).

One or more wet chemical surface or film treatments may be used to remove unwanted material, replace unwanted material with wanted material (e.g. by ionic exchange), convert the film or surface, or add material to the film. Advantageously, treatments using these techniques occur at atmospheric pressure and at temperatures between room temperature and 90° C. Additionally, it is advantageous if the treatments using these techniques can be accomplished without the use of electromagnetic sources such as ultraviolet (UV) light and/or electric fields. Examples of wet chemical surface or film treatments comprise KCN-etch, Br₂/MeOH etch, partial electrolyte treatments, acid etch, alkaline etch, NH₃ treatment, etc.

One or more heat treatments will be required after the deposition of the precursor materials using one of the deposition techniques described previously to convert the metal precursor materials into high quality, dense, semiconductor materials. As discussed previously, collectively, these processes will be called chalcogenization, two examples of which are selenization, and sulfurization. Typically, the heat treatment will further require a suitable atmosphere such as N₂, H₂, CO, H₂Se, H₂S, H₂Te, diethyl selenide (DESe), diethyl telluride (DETe), Se, S, Te, or combinations thereof. The contaminants inherently present in inks or liquid vehicle formulations might be partially or fully removed by atmospheric plasma glow discharge treatments, UV-ozone treatments, laser treatments, treatments with weak (in)organic acids, etc.

The most common conversion method involves subjecting the precursor materials to a chalcogenization process wherein the precursor materials are converted to chalcogenide materials. The substrate and the precursor materials are heated in the presence of a suitable chalcogen source (e.g., H₂Se, H₂S, H₂Te, diethyl selenide (DESe), diethyl telluride (DETe), Se, S, Te, or combinations thereof, etc.) in an atmosphere with a low O₂ and/or low H₂O content. The atmosphere typically comprises inert gases such as N₂ and/or Ar. Alternatively, the chalcogen (i.e., Se, S, Te) may be deposited as a solid (either elemental or as a suitable compound) on the surface of the precursor materials prior to the heat treatment. The chalcogen solid may be deposited using a vacuum process, an atmospheric process, a printing process, a wet coating process, other solution based processes, or some combination thereof.

Any suitable heat treating technique may be used during the conversion process. Examples comprise convective heating, conductive heating, radiative heating, or combinations thereof. Furthermore, common heating methods comprise infra-red (IR) lamps, resistive heating, muffle heating, strip heating, laser heating, flash lamps, etc.

The conversion process may be performed in a batch system or an in-line system. In the case of an in-line system, the substrate may move through the system in a continuous manner or may move through the system in a “stop-and-soak” manner, wherein the substrate moves through various process regions of the system in a step-wise manner.

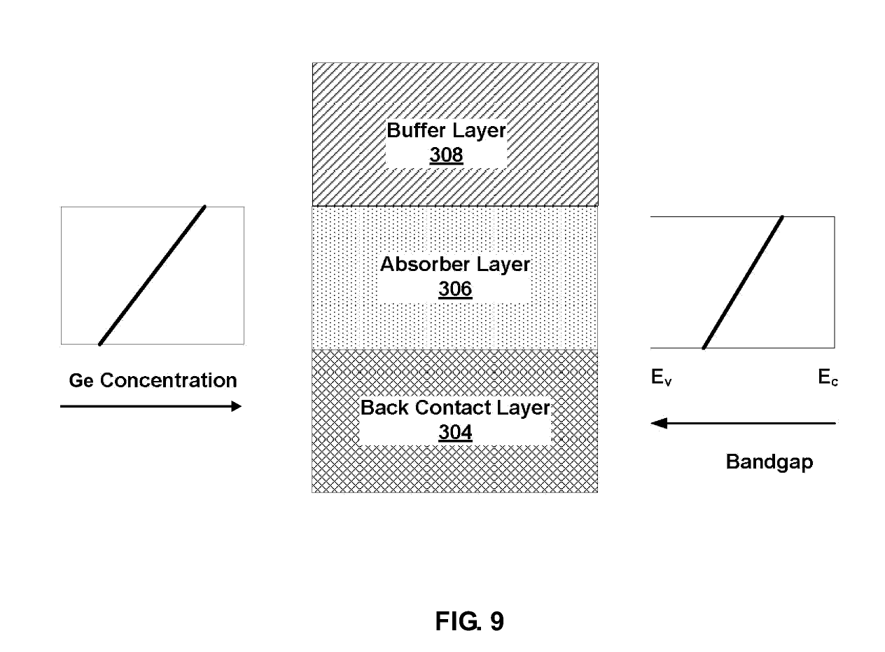

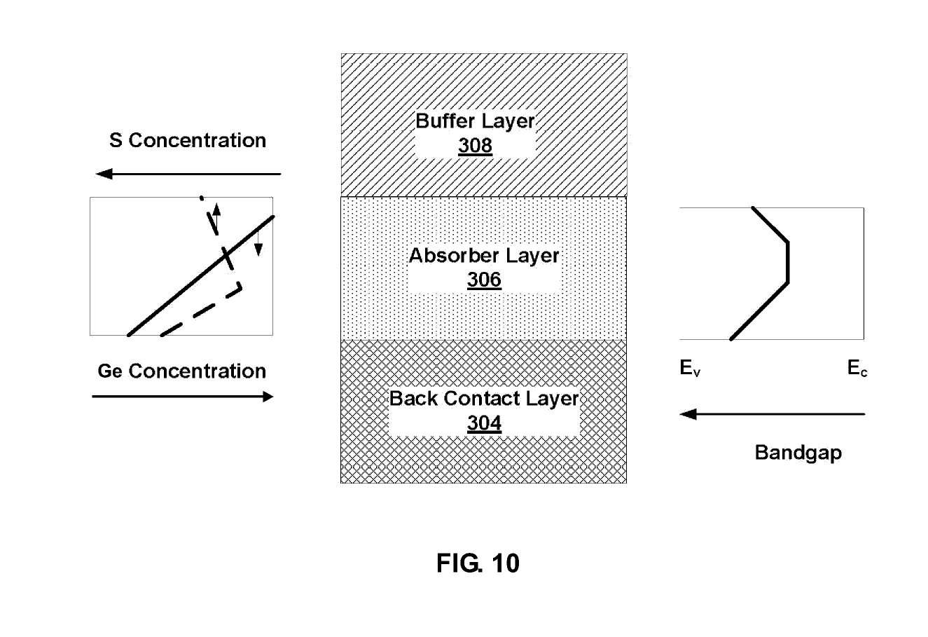

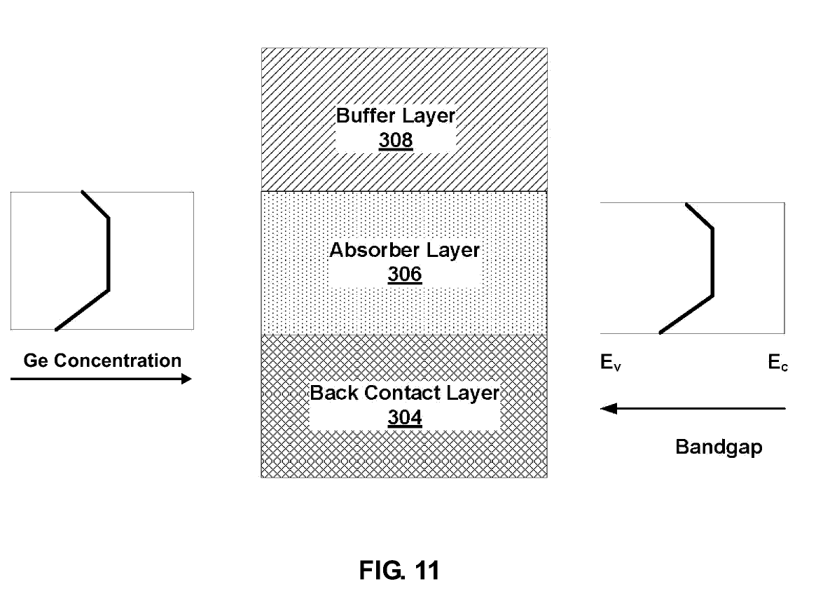

Bandgap grading is generally illustrated in FIGS. 8-11. A flat bandgap is illustrated in FIG. 8. Higher efficiencies may be obtained by single grading with a gradual increase in Ge/(Si+Ge) from the back contact to the front, so without a “notch” (also called saddle, or double grading). Forming optical absorbers with a bandgap grading containing a “notch” (also called saddle profile or double grading) has allowed even higher efficiencies to be realized in some absorbers. Bandgap grading can be achieved via compositional grading, for example, by Ge/(Si+Ge), and/or S/(S+Se). A single graded bandgap is illustrated in FIG. 9, where the Ge concentration is single graded. A double graded bandgap using Ge and/or S is illustrated in FIGS. 10 and 11. In FIG. 10, the S concentration is double graded, and a bandgap increase toward the back contact layer is enhanced by single grading of the Ge concentration. In FIG. 11, the double grading of the bandgap is provided solely by double grading of the Ge concentration.

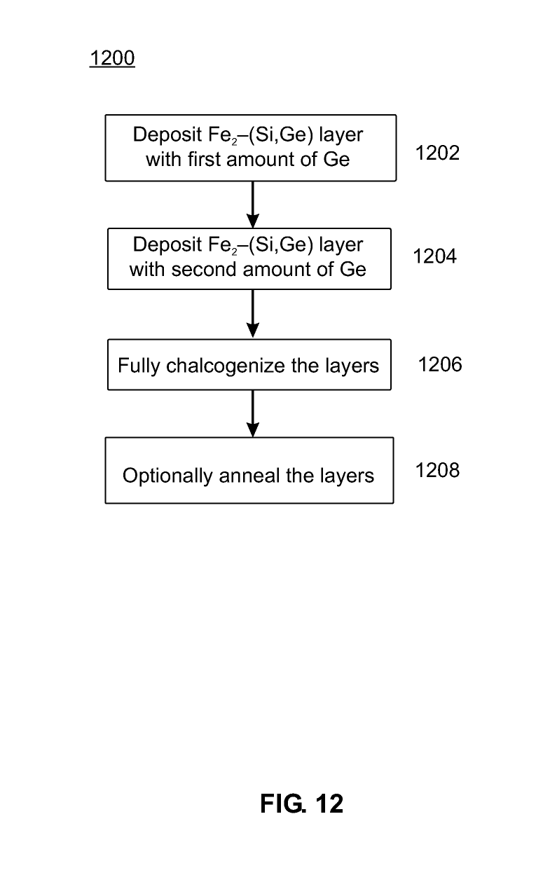

FIG. 12 sets forth a flowchart of method steps in a process sequence 1200 for forming an optical absorber layer, according to some embodiments of the invention. As shown in FIG. 12, method 1200 begins at step 1202, in which a first layer comprising Fe₂(Si,Ge) having a first specified amount of Ge is deposited on a substrate. In step 1204, a second layer comprising Fe₂(Si,Ge) having a second specified amount of Ge is deposited. The amount of Ge is different to provide a bandgap step between the two layers. In an alternative embodiment, the composition can be gradually varied as a single layer is deposited to prepare a continuously variable bandgap absorber.

At step 1206, the layers are chalcogenized. In some embodiments, the chalcogenizing atmosphere comprises sulfur or selenium, using sulfur-containing gases or selenium-containing gases. The sulfur-containing gas generally is hydrogen sulfide, while the selenium-containing gas generally comprises hydrogen selenide; both can be supplied at concentrations of between 0.1% to 100%. The reaction temperature can be between 100° C. and 600° C., with a pressure between 100 and 900 torr. It is noted that the processes described for step 1206 can be performed in the same batch furnace or in-line furnace that performs the processes of step 1202 and 1204. Consequently, implementation of method 1200 is substantially more economical and less complex than processes in which multiple processing chambers are required.

In an optional step, the bandgap can be tuned or optimized in a final anneal process. The anneal process of step 1208 can adjust the distribution of elements in the absorber layer, thereby altering the graded bandgap profile. In some embodiments, the anneal process of step 1208 is performed at a temperature greater than or equal to 500° C. It is noted that in some embodiments, depending on the reaction temperature and duration of the sulfurization or selenization process of step 1206, step 1208 may not be necessary.

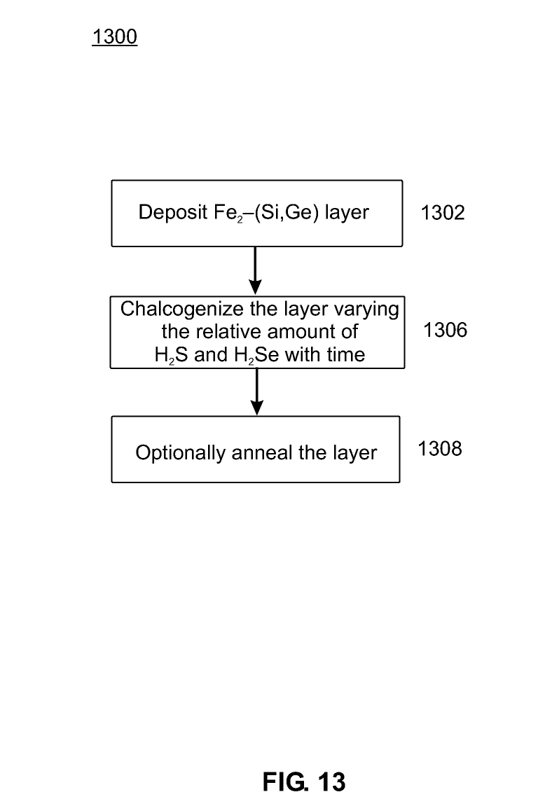

FIG. 13 sets forth a flowchart of method steps in a process sequence 1300 for forming an optical absorber layer, according to some embodiments of the invention. As shown in FIG. 13, method 1300 begins at step 1302, in which a first layer comprising Fe₂—(Si,Ge) is deposited on a substrate. At step 1306, the layers are chalcogenized. In some embodiments, the chalcogenizing atmosphere comprises sulfur or selenium, using sulfur-containing gases or selenium-containing gases. The sulfur-containing gas generally comprises hydrogen sulfide, while the selenium-containing gas generally comprises hydrogen selenide; both can be supplied at concentrations of between 0.1% to 100%. The reaction temperature can be between 100° C. and 600° C., with a pressure between 100 and 900 torr. The relative amounts of hydrogen sulfide and hydrogen selenide is varied over time of treatment, providing differential sulfurization or selenization to different portions of the layer.

It is noted that the processes described for step 1306 can be performed in the same batch furnace or in-line furnace that performs the process of step 1302. Consequently, implementation of method 1300 is substantially more economical and less complex than processes in which multiple processing chambers are required.

In step 1308, an optional anneal process can be performed on the absorber layer. The duration and temperature at which the anneal process of step 1308 takes place may be selected to adjust the bandgap profile of the absorber layer as desired. In some embodiments, the anneal process of step 1308 is performed at a temperature greater than or equal to 500° C. It is noted that the anneal process of step 1308 may be performed in the same batch furnace or in-line furnace that performs the processes of steps 1302 and 1306.

It can be appreciated that there are numerous process variations to be optimized for maximizing the efficiency of a uniform composition absorber. For graded-band-gap absorbers, there are even more variations that can be explored and optimized. These optimizations can be expedited using the High Productivity Combinatorial (HPC) techniques discussed above. While production solar panels are generally made with nominally uniform layer compositions across large device areas, it is time consuming and expensive to make large panels with each experimental process parameter variation. HPC techniques can be used to implement a large number of process parameter variations in site-isolated regions on a substrate and test each variation for desired performance characteristics.

Methods of forming an optical absorber can comprise designating a plurality of discrete site-isolated regions (SIRs) on a substrate, forming a semiconductor layer on at least one of the plurality of SIRs on the substrate, and characterizing each semiconductor layer formed on the discrete SIRs. The semiconductor generally comprises a compound of the formula Feₓ(CₐSi_{b}Ge_{c}Sn_{d}Pbₑ)(S_{f} Se_{g}Teₕ)_{y}, wherein 1.8<x<2.2, and 3.5<y<4.5, wherein a+b+c+d+e=1, and wherein f+g+h=1. The methods can further comprise varying one or more process parameters for forming each layer on the plurality of SIRs is varied in a combinatorial manner.

In the context of the novel methods for making Fe₂(Si,Ge)(S,Se)₄ absorbers disclosed herein, the process parameters that can be varied in a combinatorial manner include: process material amounts, reactant species, processing temperatures, processing times, processing pressures, processing flow rates, processing powers, processing reagent compositions, the rates at which the reactions are quenched, atmospheres in which the processes are conducted, an order in which materials are deposited. In some embodiments, the characterizing each semiconductor layer comprises measuring a structure or performance parameter for each of the plurality of site-isolated regions. In some embodiments, the structure or performance parameter is one or more of crystallinity, grain size, lattice parameter, crystal orientation, bandgap, optical absorption, efficiency, resistivity, carrier concentration, carrier mobility, minority carrier lifetime, optical absorption coefficient, surface roughness, adhesion, or thermal expansion coefficient.

In the context of the novel PVD methods for making Fe₂(Si,Ge)(S,Se)₄ absorbers disclosed herein, the process parameters that can be varied in a combinatorial manner include: sputtering power, sputtering atmosphere composition, sputtering time, substrate temperature, substrate bias, annealing temperature and time, number of sets of layers, and co-deposition vs. sequential layers. For example, absorber layers can be prepared using elemental targets comprising Fe, Si, and Ge, sputtered in an inert atmosphere followed by chalcogenization and annealing. An HPC experiment for this process can include combinatorial variations in sputtering power; sputtering time; substrate bias, sputtering atmosphere pressure; number of sets of layers; co-deposition vs. sequential layers; substrate temperature during sputtering, chalcogenization, and annealing; and chalcogenization atmosphere composition (e.g., % H₂S in (H₂S+H₂Se)). Absorber bandgap variations can be explored by varying the amount of material sputtered from each of the sputtering targets, e.g., by varying the sputtering powers supplied to the targets or the sputtering times for each target, and so forth. Substrate bias and temperature can be varied to ascertain the influence of crystalline form prepared under the different conditions on bandgap, absorber efficiency, carrier mobility, adhesion between layers in the solar cell, and so forth. The use or omission of annealing steps can be utilized to determine the influence of this parameter on absorber layer structure, composition and performance. Bandgap grading through the absorber layer using compositional variations can be explored using additional targets comprising grading elements such as C, Sn, Pb and Te, and by using different chalcogenizing atmospheres, times and temperatures. Similar experiments can be designed for binary targets, ternary targets, quaternary targets, and quinternary targets and processes that include deposition methods other than PVD.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A method of forming an optical absorber, the method comprising:
forming a first layer on a substrate, wherein the first layer comprises Fe and at least one Group IVA element, wherein the first layer contains substantially no O; and
providing a gas to the first layer, wherein the gas comprises at least one Group VIA element,
wherein the optical absorber has a bandgap between 1.0 eV and 1.6 eV.

2. The method of claim 1, wherein the Group IVA element is Si or Ge, and the Group VIA element is S, Se or Te.

3. The method of claim 1, wherein the optical absorber comprises a compound having a formula Feₓ(CₐSi_{b}Ge_{c}Sn_{d}Pbₑ)(S_{f} Se_{g}Teₕ)_{y}, wherein 1.8<x<2.2, and 3.5<y<4.5, wherein a+b+c+d+e=1, and wherein f+g+h=1.

4. The method of claim 3, wherein the bandgap is graded through a thickness of the optical absorber by varying one or more of {a, b, c, d, e} or one or more of {f, g, h}.

5. The method of claim 3, wherein the optical absorber comprises a compound having a formula Feₓ(Si_{b}Ge_{1-b})(S_{f}Se_{1-f})_{y}, where x=2, y=4, 0≦b≦1, and 0≦f≦1.

6. The method of claim 5, wherein the bandgap is graded through a thickness of the optical absorber by varying one or more of b or f.

7. The method of claim 1, wherein a thickness of the first layer is between 1 micron to 10 microns.

8. The method of claim 1, further comprising
forming a second layer on the first layer, and
providing a second gas to the second layer, wherein the second gas comprises at least one Group VIA element;
wherein the second layer comprises Fe and at least one Group IVA element.

9. The method of claim 8, wherein a bandgap of the second layer is different from the bandgap of the first layer.

10. The method of claim 8, further comprising, annealing one or more of the first layer or the second layer at a temperature of between 350° C. and 650° C.

11. The method of claim 8, wherein the providing the second gas further comprises heating at a temperature of between 100° C. and 600° C.

12. The method of claim 1, wherein the forming a first layer is performed by physical vapor deposition (PVD) from one or more sputtering targets,
wherein at least one sputtering target comprises Fe, and at least one sputtering target comprises a Group IVA element.

13. The method of claim 12, wherein the one or more sputtering targets comprise elemental targets, binary targets, ternary targets, quaternary targets or quinternary targets.

14. The method of claim 13, wherein each elemental target comprises Fe, Si, or Ge.

15. The method of claim 12, wherein the PVD deposition comprises reactive sputtering in an atmosphere comprising one or more of S or Se.

16. The method of claim 13, wherein each binary target comprises one of Fe and S, Fe and Se, Fe and Si, Fe and Ge, Si and S, Si and Se, Si and Ge, Ge and S, or Ge and Se.

17. The method of claim 13, wherein each ternary target comprises one of Fe, Si, and S; Fe, Si, and Se; Fe, Ge, and S; Fe, Ge, and Se; Fe, Si and Ge, Si, Ge and S, or Si, Ge and Se.

18. The method of claim 13, wherein each quaternary target comprises one of Fe, Si, Ge, and S; Fe, Si, Ge, and Se; Fe, Si, S and Se; or Fe, Ge, S and Se.

19. The method of claim 12, further comprising grading the bandgap of the absorber,
wherein grading the bandgap comprises varying the relative amount of material sputtered from each of the one or more sputtering targets through the thickness of the layer.

20. A solar cell comprising an optical absorber made by the method of claim 1.
